(19) United States
(12) Patent Application Publication
(10) Pub. No.: US 2026/0040506 A1
(43) Pub. Date: Feb. 5, 2026

(54) ELECTRONIC CONTROL DEVICE

(71) Applicant: HITACHI ASTEMO, LTD., Hitachinaka-shi, Ibaraki (JP)

(72) Inventor: Michihito WATARAI, Hitachinaka-shi, Ibaraki (JP)

(73) Assignee: HITACHI ASTEMO, LTD., Hitachinaka-shi, Ibaraki (JP)

(21) Appl. No.: 19/099,114

(22) PCT Filed: Aug. 3, 2022
(86) PCT No.: PCT/JP2022/029835

§ 371 Date: Jan. 28, 2025

(51) Int. Cl. H05K 7/20

(52) U.S. Cl. CPC H05K 7/20863; H05K 7/20145; H05K 7/20163; H05K 7/20172; H05K 7/20209

(57) ABSTRACT

An electronic control device (1) includes: a housing (2) adapted to seal and house a circuit board (6); first heat dissipation fins (21a) provided on the lower surface of the housing (2); second heat dissipation fins (22a) provided on the upper surface of the housing (2); an air duct (4) attached to the outer side of the housing (2) so as to cover the first heat dissipation fins and the second heat dissipation fins and adapted to form a cooling air flow path for flowing cooling air therethrough near the upper surface and the lower surface of the housing (2); and cooling fans (8) installed downstream of the heat dissipation fins (21a, 22a) positioned in a downstream side of the cooling air flow path, out of the first heat dissipation fins (21a) and the second heat dissipation fins (22a), and adapted to exhaust cooling air toward the downstream side of the cooling air flow path. The cooling air flow path is formed to be a single flow path without branching, through a portion from the first heat dissipation fins (21a) up to the second heat dissipation fins (22a).

### TECHNICAL FIELD

The present invention relates to electronic control devices.

### BACKGROUND ART

Along with improvement in performance of electronic control units (ECUs), it is impossible to sufficiently cool the electronic control units through natural air cooling, due to increases of heat generation therefrom. Therefore, developments have been conducted for electronic control devices equipped with cooling fans for forced air cooling.

In such an electronic control device equipped with cooling fans, if cooling air is directly blown to a plurality of electronic components mounted on a circuit board (which will be referred to as a plurality of electronic components, hereinafter) for cooling them, dust is deposited thereon, which may cause degradation of the cooling capacity, short-circuiting due to intrusion of conductive foreign substances, and the like. For coping therewith, Patent Literatures disclose electronic control devices adapted to indirectly cool a plurality of electronic components without directly blowing cooling air to the plurality of electronic components.

For example, PTL 1 discloses an electronic control device (electronic device) including a cooling fan (air blowing unit): installed on the upper surface of a case storing a circuit board having a plurality of electronic components mounted thereon (a printed circuit board having circuit elements mounted thereon), in which air flows generated from the cooling fan are along the upper surface of the case, thereby indirectly cooling the plurality of electronic components.

### CITATION LIST

### Patent Literature

PTL 1: JP 2018-206964 A

### SUMMARY OF INVENTION

### Technical Problem

A flow path configuration adapted to disperse cooling air discharged from a cooling fan into a plurality of flow paths as that in PTL 1 can be regarded as having the plurality of flow paths with respective different flow path resistances (for example, flow path cross-sectional areas) which are arranged in parallel. Therefore, the distribution of the air volume into the respective flow paths is determined according to the flow path resistances of the respective flow paths.

In this flow path configuration, changing the flow path resistance of one flow path affects the distribution of the air volume into all the flow paths. This makes it difficult to flow necessary air volumes into the respective flow paths. This makes it difficult to implement cooling design. In particular, in PTL1, cooling air generated from one cooling fan is distributed into the plural flow paths arranged therearound, which makes it harder to control the distribution of the air volume into the respective flow paths. Accordingly, a theoretical value of the distributed air volume tends to deviate from the actual value, which also increases the difficulty of designing.

Furthermore, in a case of cooling, by cooling air, both the upper and lower surfaces of a housing (case) storing a circuit board, an increased number of objects are to be cooled, which further increases the difficulty of cooling design.

It is an object of the present invention to provide an electronic control device which facilitates cooling design for cooling upper and lower surfaces of a housing storing a circuit board.

### Solution to Problem

In order to attain the aforementioned object, according to the present invention, there are provided a circuit board having a plurality of electronic components mounted thereon; a housing adapted to seal and house the circuit board; a first heat dissipation fin comprising a plurality of protrusions provided on a lower surface of the housing; a second heat dissipation fin comprising a plurality of protrusions provided on an upper surface of the housing; an air duct attached to an outer side of the housing so as to cover the first heat dissipation fin and the second heat dissipation fin and adapted to form a cooling air flow path for flowing cooling air therethrough near the upper surface and the lower surface of the housing; and a cooling fan installed downstream of the heat dissipation fin positioned in a downstream side of the cooling air flow path, out of the first heat dissipation fin and the second heat dissipation fin, and adapted to exhaust cooling air toward a downstream side of the cooling air flow path; in which the cooling air flow path is formed to be a single flow path without branching, through a portion from the first heat dissipation fin up to the second heat dissipation fin.

### Advantageous Effects of Invention

The present invention facilitates cooling design for cooling the upper and lower surfaces of a housing that houses a circuit board, thereby simplifying the housing design. Other problems, structures, and advantages than those described above will be clarified by the following description of embodiments.

### BRIEF DESCRIPTION OF DRAWINGS

FIG. 1 is a perspective view of an electronic control device according to a first embodiment of the present invention as viewed from forward thereof, the right thereof and thereabove.

FIG. 2 is a perspective view of the electronic control device according to the first embodiment of the present invention as viewed from left thereof, thereabove and therebehind.

FIG. 3 is a developed perspective view of the electronic control device according to the first embodiment of the present invention.

FIG. 4 is a perspective view of a housing in a state where a cover-side air duct and a cover are removed from the electronic control device according to the first embodiment of the present invention, thereby exposing a circuit board.

FIG. 5 is a cross-sectional view taken along a line A-A in FIG. 2.

FIG. 6 is a perspective view of a power supply connector according to the first embodiment of the present invention.

FIG. 7 is a cross-sectional view taken along a line B-B in FIG. 4.

FIG. 8 is a cross-sectional view taken along a line C-C in FIG. 2.

FIG. 9 is an enlarged view of cooling fans and the fan connectors attached to a base-side air duct according to the first embodiment of the present invention.

FIG. 10 is an enlarged perspective view of a connector fixing portion provided in the base-side air duct according to the first embodiment.

FIG. 11 is an enlarged perspective view of the fan connector attached to the connector fixing portion in the base-side air duct according to the first embodiment of the present invention.

FIG. 12 is a cross-sectional view taken along a line D-D in FIG. 11.

FIG. 13 is a cross-sectional perspective view taken along a line E-E in FIG. 12.

FIG. 14 is partial perspective views illustrating the electronic control device according to the first embodiment of the present invention, in states before and after attaching convex portions in the base-side air duct to concave portions in the cover.

FIG. 15 is a perspective view of the housing and a subassembly in the electronic control device according to the first embodiment of the present invention.

FIG. 16 is a partial cross-sectional perspective view of the rear sides of the housing and the cover to which the subassembly is attached, in the electronic control device according to the first embodiment of the present invention.

FIG. 17 is a cross-sectional view taken along a line F-F in FIG. 2.

FIG. 18 is partial perspective views illustrating the electronic control device according to the first embodiment, in states before and after attaching guides in a cover-side air duct to convex portions in the cover.

FIG. 19 is partial perspective views illustrating the electronic control device according to the first embodiment of the present invention, in states before and after being attached to a vehicle-side bracket CB.

FIG. 20 is a perspective view of a subassembly according to a second embodiment of the present invention.

FIG. 21 is a cross-sectional view taken along a line G-G in FIG. 20.

FIG. 22 is a rear view of an electronic control device according to the second embodiment of the present invention.

FIG. 23 is a perspective view of an electronic control device according to a third embodiment of the present invention, as viewed from the left thereof, thereabove and therebehind.

FIG. 24 is a perspective view of the electronic control device according to the third embodiment of the present invention, as viewed from the left thereof, therebelow and therebehind.

FIG. 25 is a cross-sectional view taken along a line I-I in FIG. 24.

FIG. 26 is a cross-sectional view taken along a line H-H in FIG. 23.

FIG. 27 is a perspective view illustrating a direction of cooling air flowing through a cooling air flow path formed in a base-side air duct, in the event of stop of one of two cooling fans included in the electronic control device according to the third embodiment of the present invention.

FIG. 28 is a perspective view of an electronic control device according to a fourth embodiment of the present invention as viewed from the left thereof, thereabove and therebehind.

FIG. 29 is a cross-sectional view taken along a line J-J in FIG. 28.

FIG. 30 is a perspective view of a rear side of a back surface of a housing according to the fourth embodiment of the present invention.

### DESCRIPTION OF EMBODIMENTS

Hereinafter, electronic control devices according to first to fourth embodiments of the present invention will be described, regarding their structures and operations, with reference to the drawings. In the drawings, the same reference numerals denote the same portions. In each of the drawings, directions are specified by XYZ axes orthogonal to each other, in which +X is defined as “right”, −X is defined as “left”, +Y is defined as “upper”, −Y is defined as “lower”, +Z is defined as “front”, and −Z is defined as “rear”.

### First Embodiment

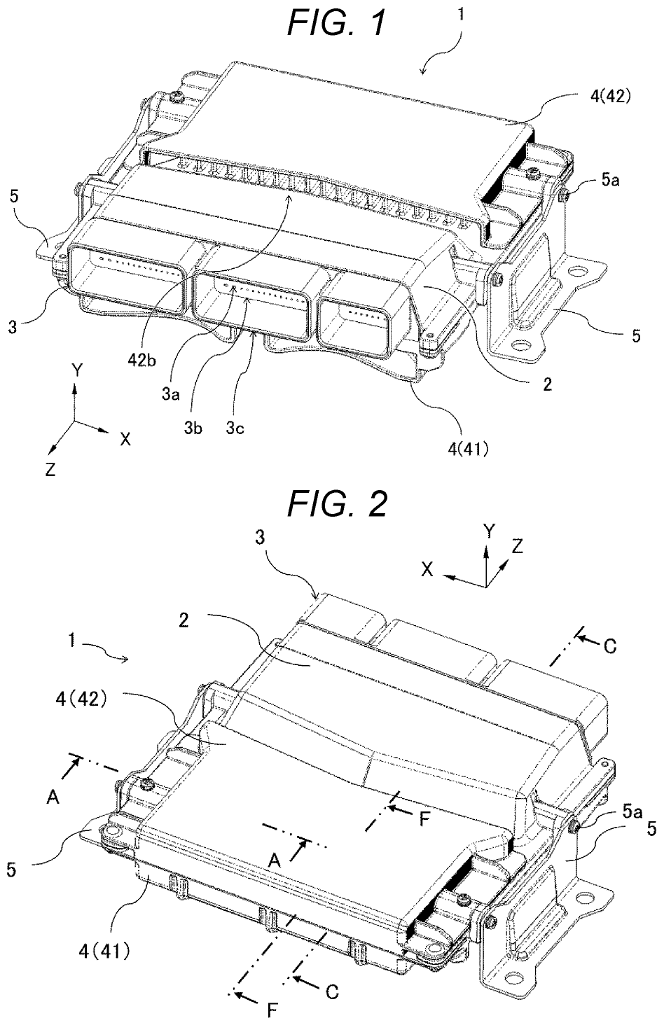

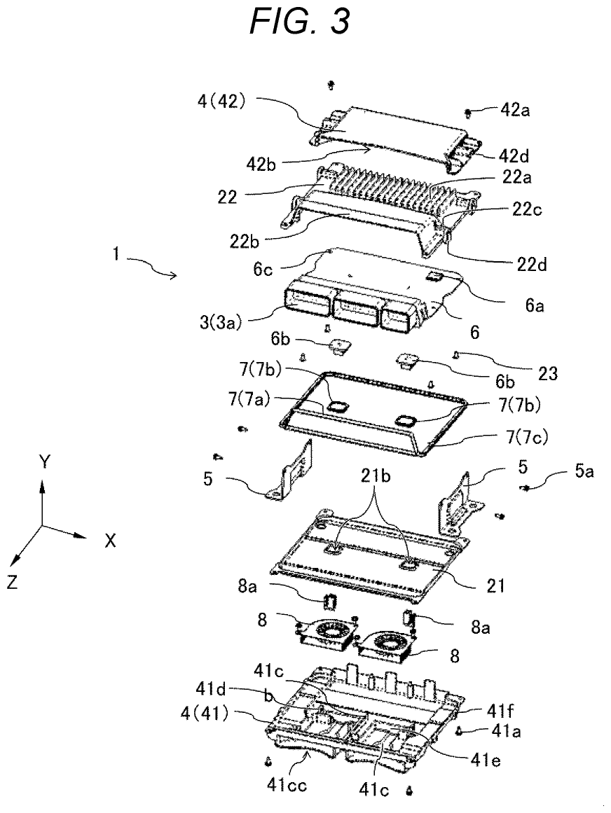

FIG. 1 is a perspective view of an electronic control device 1 according to a first embodiment of the present invention as viewed from forward thereof, the right thereof and thereabove. FIG. 2 is a perspective view of the electronic control device 1 according to the first embodiment of the present invention as viewed from the left thereof, thereabove and therebehind. FIG. 3 is a developed perspective view of the electronic control device 1 according to the first embodiment of the present invention.

The electronic control device 1 is one type of computer, and is an electronic control unit (ECU) which is mounted in a configuration in an automobile and is incorporated in the automobile. For example, the electronic control device 1 is mounted in an engine room in an automobile.

As illustrated in FIGS. 1 and 2, the electronic control device 1 includes a housing 2, an external connection connector 3, an air duct 4, and device-side brackets 5. As illustrated in FIG. 3, the housing 2 can be developed into a base 21 and a cover 22 for sandwiching a circuit board 6 therebetween to house the circuit board 6, and the air duct 4 can be developed into a base-side air duct 41 and a cover-side air duct 42 for sandwiching the housing 2 therebetween to cover the housing 2.

The housing 2 is a component for sealing and housing the circuit board 6, and includes the base 21 and the cover 22, as described above.

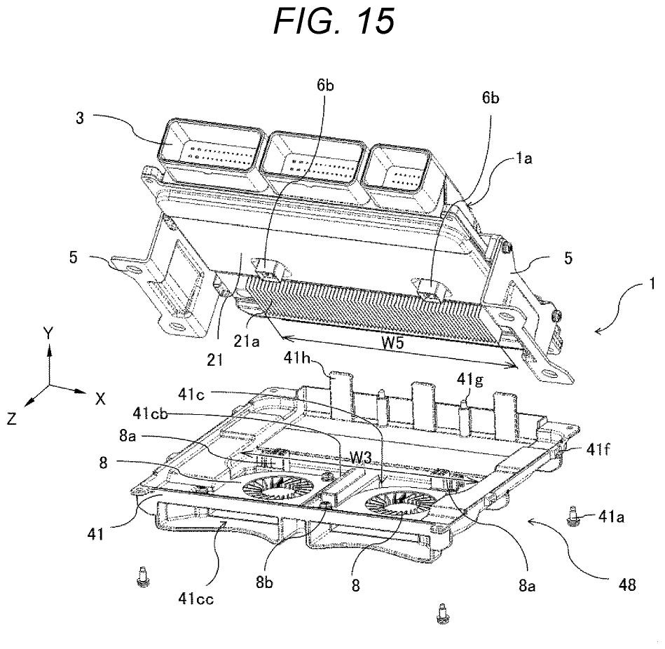

The base 21 is a flat plate-shaped component for covering the lower surface of the circuit board 6, and is formed from, for example, a metal mainly containing aluminum, iron, or the like. The base 21 is provided, on its lower surface, with first heat dissipation fins (base-side heat dissipation fins 21a) (see FIGS. 8 and 15).

The base-side heat dissipation fins 21a are a plurality of protrusions provided on the lower surface of the base 21. Specifically, the base-side heat dissipation fins 21a are a plurality of thin plate-shaped protrusions protruding downward from the lower surface of the base 21 and extending in the forward and rearward direction so as to be arranged in parallel in the leftward and rightward direction (see FIG. 15). The base-side heat dissipation fins 21a dissipate heat generated from electronic components 6a and the like mounted on the circuit board 6.

When the base 21 is made of an aluminum plate material, the base-side heat dissipation fins 21a are preferably formed by skiving (slicing a surface layer of the lower surface of the base 21 and bending the basal portions of the slice portions for raising them (scraping)). When the base 21 is formed by aluminum die-casting, it is preferable that the base-side heat dissipation fins 21a are formed by casting.

Further, in order to cause power supply connectors 6b secured to the circuit board 6 to protrude toward fan connectors 8a secured to the base-side air duct 41, the base 21 is provided with through holes 21b for causing the power supply connectors 6b to protrude (see FIG. 3).

The cover 22 is a component for covering the upper surface of the circuit board 6, and is formed from, for example, a metal mainly containing aluminum, iron, or the like. Preferably, the cover 22 is provided with second heat dissipation fins (cover-side heat dissipation fins 22a) on a rear side of its upper surface (see FIGS. 3 and 8), and is provided, in its lower surface, with screw holes (not illustrated) for screws 23 for securing the circuit board 6 thereto.

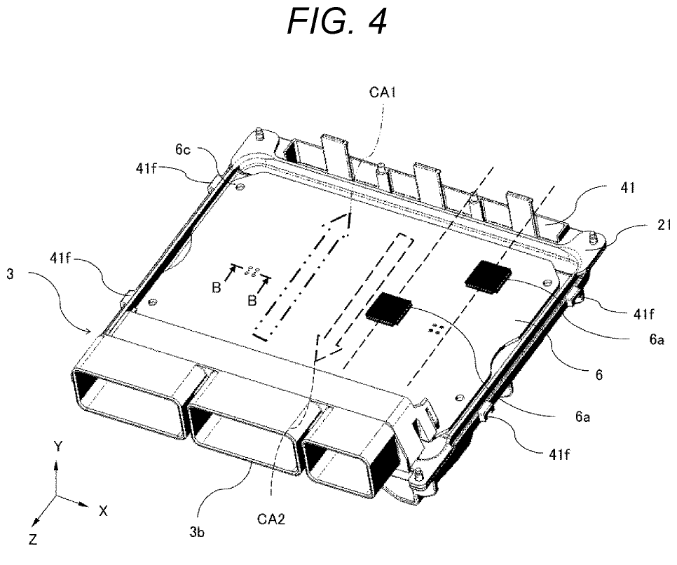

Further, the cover 22 is provided, in its front side, with a connector cover portion 22b which covers the upper portion of the external connection connector 3 and has an opening for forwardly protruding the connector portion of the external connection connector 3. Further, the cover 22 is provided, in left and right ends of its upper surface, with a plurality of positioning male portions 22c (see FIG. 18) to be assembled with positioning female portions 42g in the cover-side air duct 42. On the outer sides of the plurality of positioning male portions 22c, there are provided protrusions 22e each having a positioning female portion 22d in its lower surface, in which the positioning female portion 22d is to be assembled with a positioning male portion 41f (see FIG. 4) in the base-side air duct 41 (see FIG. 14).

The cover-side heat dissipation fins 22a are a plurality of protrusions provided on the upper surface of the cover 22. Specifically, the cover-side heat dissipation fins 22a are a plurality of thin plate-shaped protrusions protruding upward from the upper surface of the cover 22 and extending in the forward and rearward direction so as to be arranged in parallel in the leftward and rightward direction. The cover-side heat dissipation fins 22a dissipate heat generated from the electronic components 6a and the like mounted on the circuit board 6.

The cover 22 is provided with the cover-side heat dissipation fins 22a, the connector cover portion 22b, the positioning male portions 22c, the positioning female portions 22d, and the protrusions 22e, and has a complicated shape. Therefore, the cover 22 is preferably formed by casting, and is preferably formed by aluminum die-casting.

The circuit board 6 is preferably secured to the lower surface of the cover 22 through the screws 23. The cover 22 and the base 21 are preferably assembled to each other through screws 41a (see FIG. 3) for attaching the base-side air duct 41 to the cover 22, which will be described later.

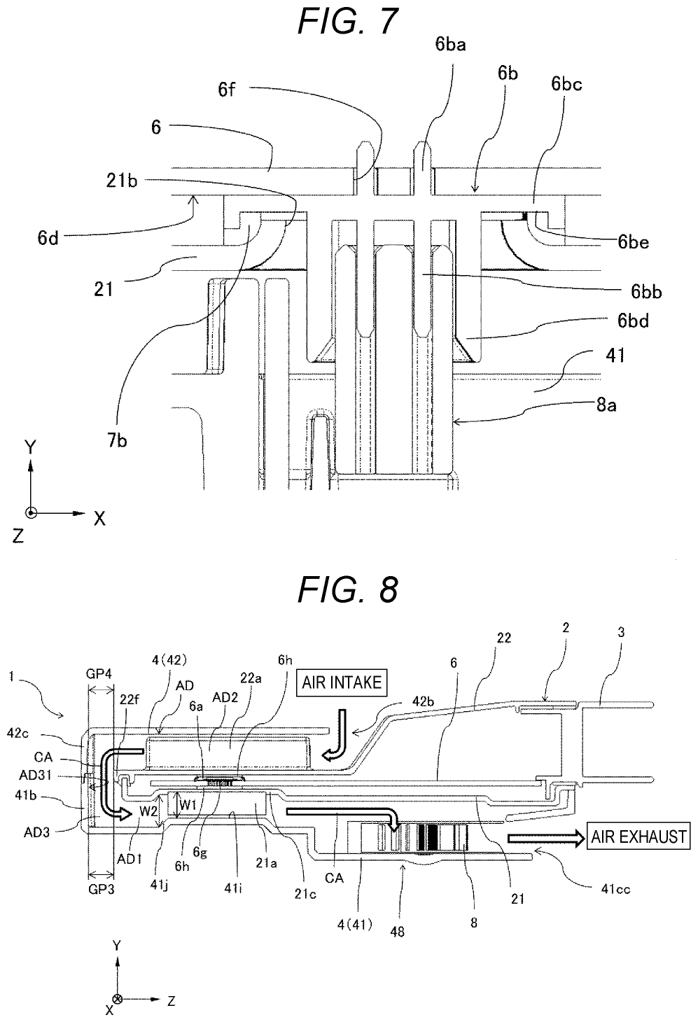

The circuit board 6 is a printed-circuit board, on which, for example, a plurality of electronic components 6a are surface-mounted, and the power supply connectors 6b and the like are secured to through holes 6f (see FIG. 7) provided in the circuit board 6 through soldering, press-fitting, spot flow, or the like. As illustrated in FIG. 3, the circuit board 6 preferably includes through holes 6c, and is preferably secured to the cover 22 through the screws 23 inserted into the through holes 6c.

As illustrated in FIG. 3, the external connection connector 3 is a component that is provided forward of the circuit board 6 and electrically connects an electronic circuit on the circuit board 6 and an electronic component in a vehicle to each other. As illustrated in FIG. 1, the external connection connector 3 includes a plurality of connector terminals 3a.

The plurality of connector terminals 3a is formed from a metal mainly containing copper and is insulated and fixed by being covered with an insulator 3b. The plurality of connector terminals 3a is electrically connected, at one end portion thereof, to an electronic circuit provided on the circuit board 6, and is adapted such that an external terminal can be electrically connected to the other end portion thereof.

Further, plugs 3c protrude forward from the outer peripheries of the insulators 3b covering the plurality of connector terminals 3a, which enables assembling, thereto, a connector (not illustrated) at the tip end of a harness extending from an electronic component in the vehicle.

The insulators 3b and the plugs 3c are preferably made of a resin such as polybutylene terephthalate (PBT), polyamide (PA), or polyphenylene sulfide (PPS), for example.

A first sealing material 7a (see FIG. 3) is interposed between the external connection connector 3 and the base 21 and the cover 22. This prevents dust, water, and the like from being sucked into the housing 2 through between the external connection connector 3 and the housing 2.

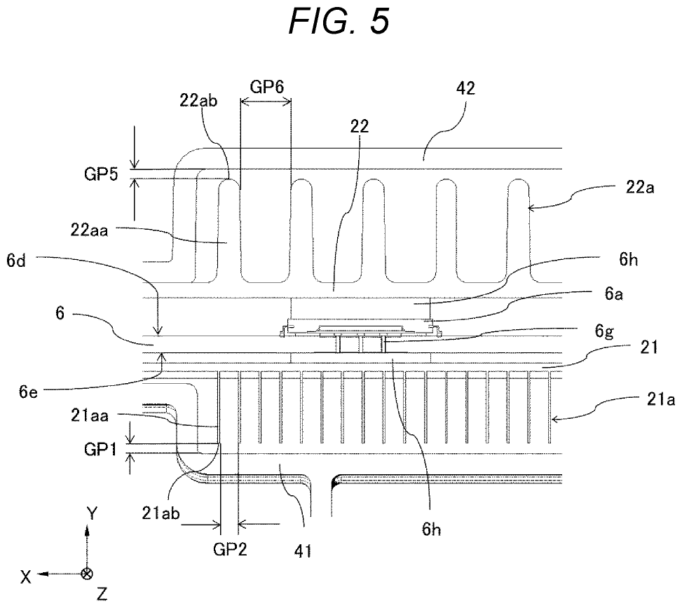

FIG. 4 is a perspective view of the housing 2 in a state where the cover-side air duct 42 and the cover 22 are removed from the electronic control device 1 according to the first embodiment of the present invention, thereby exposing the circuit board 6. FIG. 5 is a cross-sectional view taken along a line A-A in FIG. 2.

As illustrated in FIG. 4, a plurality of electronic components 6a are mounted on the circuit board 6. FIG. 4 briefly illustrates the plurality of electronic components 6a, and a large number of electronic components 6a are mounted on the upper surface and the lower surface of the circuit board 6.

The plurality of electronic components 6a is a plurality of components constituting an electronic circuit, and includes an element that generates heat such as a semiconductor element, a package of an integrated circuit such as a ball grid array (BGA) or a quad flat package (QFP), and the like, for example.

Preferably, the plurality of electronic components 6a are mounted in parallel with respect to the direction of flow of cooling air. For example, as illustrated in FIG. 4, it is preferable that the plurality of electronic components 6a are mounted in parallel (at different positions in the leftward and rightward direction on the circuit board 6) with respect to cooling air CAL flowing from the front to the back along the upper surface of the cover 22 (not illustrated) and cooling air CA2 flowing from the back to the front along the lower surface of the base 21.

Further, preferably, the plurality of electronic components 6a are in contact with the housing 2 (the base 21 and the cover 22) with a heat dissipation grease 6h such as silicon grease interposed therebetween. For example, as illustrated in FIG. 5, the heat dissipation grease 6h may be applied to the electronic components 6a mounted on the upper surface 6d of the circuit board 6, thereby bringing the electronic components 6a into contact with the cover 22. Further, the heat dissipation grease 6h may be applied to the electronic components 6a mounted on the lower surface 6e of the circuit board 6, thereby bringing the electronic components 6a into contact with the base 21. This enables efficiently dissipating heat generated from the electronic components 6a mounted on the circuit board 6, thereby improving the heat dissipation performance.

Further, the electronic components 6a may be thermally conductively connected to the base 21, through a thermal conductor (thermal vias 6g) penetrating the circuit board 6 and protruding to the lower surface of the circuit board 6, and the heat dissipation grease 6h applied to the lower surface 6e of the circuit board 6. In this case, as illustrated in FIG. 8 which will be described later, a plate-shaped portion (a fin-formed plate portion 21c) including the base-side heat dissipation fins 21a, in the base 21, may be raised upward (toward the circuit board 6), in order to narrow the gap between the circuit board 6 and the upper surface of the base 21. This facilitates thermally conductively connecting the thermal vias 6g to the base 21 through the heat dissipation grease 6h, thereby improving the heat dissipation performance.

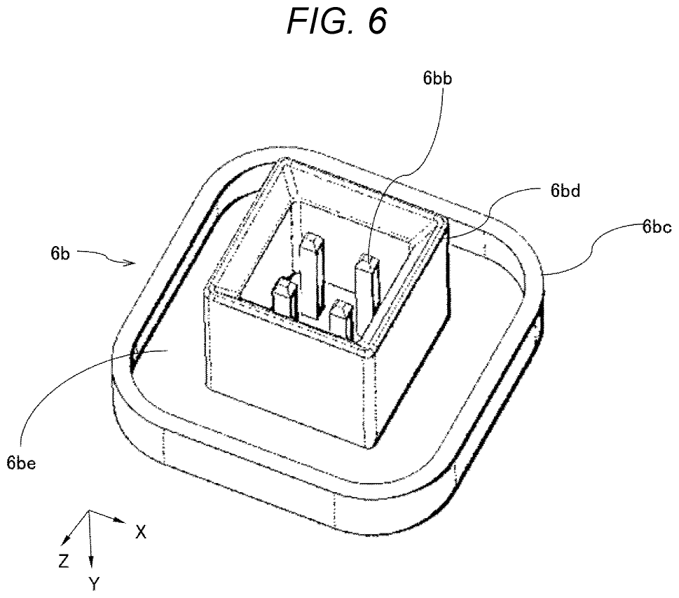

FIG. 6 is a perspective view of a power supply connector 6b according to the first embodiment of the present invention. FIG. 7 is a cross-sectional view taken along a line B-B in FIG. 4. The power supply connector 6b is a connector for supplying electricity to a cooling fan 8 through a fan connector 8a, which will be described later. Preferably, the power supply connector 6b is attached to the circuit board 6 and inserted into the through hole 21b provided in the housing 2, and a second sealing material 7b is provided in a gap formed between the through hole 21b and the power supply connector 6b.

For example, as illustrated in FIGS. 6 and 7, the power supply connector 6b is provided with board-side terminals 6ba protruding upward (toward the board), cooling-fan-side terminals 6bb protruding downward (toward the cooling fan), a plate-shaped portion 6bc supporting both the terminals 6ba and 6bb, and a box-shaped member 6bd protruding downward from the plate-shaped portion 6bc.

Preferably, the board-side terminals 6ba are inserted in through holes 6f in the circuit board 6 and are attached to the circuit board 6 through soldering, press-fitting, or spot flow, for example, to be electrically connected to the circuit board 6, as illustrated in FIG. 7. Preferably, the board-side terminals 6ba are adhered to the circuit board 6 through soldering or the like to secure the power supply connector 6b to the circuit board 6. As illustrated in FIG. 7, the cooling-fan-side terminals 6bb are a plurality of terminals inserted into the fan connector 8a, and are electrically connected to terminals in the fan connector 8a.

As illustrated in FIGS. 6 and 7, the plate-shaped portion 6bc is a rectangular plate-shaped portion extending forward, rearward, leftward and rightward. The upper surface of the plate-shaped portion 6bc abuts on the circuit board 6, thereby defining the inclination of the power supply connector 6b with respect to the circuit board 6. Preferably, the plate-shaped portion 6bc is provided, in its lower surface, with a groove 6be along an outer surface of the box-shaped member 6bd. Preferably, the second sealing material 7b is applied to the groove 6be.

The box-shaped member 6bd is a member for covering the side surfaces of the cooling-fan-side terminals 6bb, as illustrated in FIG. 6, and is inserted in the through hole 21b in the base 21 to protrude from the lower surface of the base 21, as illustrated in FIG. 7 (see FIG. 15). Since the box-shaped member 6bd is protruded through the through hole 21b in the base 21, the second sealing material 7b applied to the groove 6be is bonded to the upper surface of the base 21 around the through hole 21b. As a result, the second sealing material 7b closes the gap between the plate-shaped portion 6bc of the power supply connector 6b and the through hole 21b in the base 21, thereby sealing the periphery of the through hole 21b in the base 21.

The sealing material 7 is a component for sealing the circuit board 6 inside the housing 2, and includes the first sealing material 7a, the second sealing materials 7b, and a third sealing material 7c, as illustrated in FIG. 3.

The first sealing material 7a is a sealing material 7 for preventing dust, water, and the like from being sucked into the housing 2 through between the external connection connector 3 and the housing 2, and is provided between the base 21 or the cover 22 and the external connection connector 3, as described above.

Each second sealing material 7b is a sealing material 7 for preventing dust, water, and the like from being sucked into the housing 2 through between the power supply connector 6b and the through hole 21b, and is provided between the plate-shaped portion 6bc of the power supply connector 6b and the through hole 21b in the base 21, as described above.

The third sealing material 7c is a sealing material 7 for preventing dust, water, and the like from being sucked into the housing 2 through the gap between the base 21 and the cover 22, and is provided between the base 21 and the cover 22.

The sealing material 7 is constituted by, for example, an adhesive agent made of a silicon-based, epoxy-based, or urethane-based material or other materials, or an O-ring formed from a rubber-based material.

By causing the circuit board 6 to which the external connection connector 3, the electronic components 6a, and the power supply connectors 6b have been attached, to be housed by the base 21 and the cover 22, in such a way as to seal the circuit board 6 by the sealing material 7, the housing 2 is formed.

FIG. 8 is a cross-sectional view taken along a line C-C in FIG. 2. As illustrated in FIG. 8, the air duct 4 (the base-side air duct 41 and the cover-side air duct 42) is a component that is attached to the outer side of the housing 2 so as to cover the first heat dissipation fins (the cover-side heat dissipation fins 22a) and the second heat dissipation fins (the base-side heat dissipation fins 21a), and forms a cooling air flow path AD for flowing cooling air CA therethrough near the upper surface (the upper surface of the cover 22) and the lower surface (the lower surface of the base 21) of the housing 2.

As illustrated in FIG. 8, the base-side air duct 41 is a component attached to the housing 2 so as to cover the base-side heat dissipation fins 21a (the second heat dissipation fins) provided on the lower surface of the base 21, thereby forming the cooling air flow path AD on the lower surface of the housing 2 (the base 21). The base-side air duct 41 is secured to the housing 2 through screws 41a (see FIG. 3).

It is preferable that a gap GP1 is formed between the base-side air duct 41 attached to the housing 2 and the tip ends 21ab of the plurality of protrusions 21aa included in the base-side heat dissipation fins 21a, as illustrated in FIG. 5.

Preferably, the dimension of the gap GP1 is set such that the flow rate of cooling air passing through the gap GP1 is smaller than the flow rate of cooling air passing through an interval GP2 between two adjacent protrusions 21aa out of the plurality of protrusions 21aa included in the base-side heat dissipation fins 21a.

The base-side air duct 41 has a rear wall 41b formed so as to be separated from a rear end portion 22f of the cover 22, as illustrated in FIG. 8. This causes formation of a gap GP3 for flowing cooling air CA therethrough between the rear wall 41b and the rear end portion 22f.

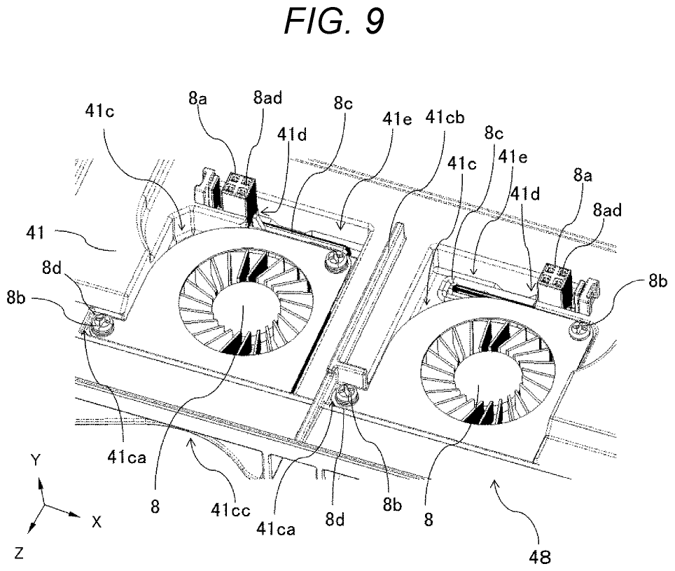

FIG. 9 is an enlarged view of the cooling fans 8 and the fan connectors 8a attached to the base-side air duct 41 according to the first embodiment of the present invention. As illustrated in FIGS. 3 and 9, the base-side air duct 41 is preferably provided with fan fixing portions 41c for fixing the cooling fans 8, connector fixing portions 41d for fixing the fan connectors 8a, and cable storage portions 41e for storing cables.

Each fan fixing portion 41c is a portion formed in conformance with the shape of the cooling fan 8 and adapted to fix the cooling fan 8 assembled thereto through screws 8b. Preferably, the base-side air duct 41 provided with the fan fixing portions 41c is provided with attachment-surface limiting configurations 41ca for limiting the attachment surfaces of the cooling fans 8 (the surfaces of the cooling fans 8 which are closer to the base-side air duct 41 when the cooling fans 8 are attached to the base-side air duct 41).

Each attachment-surface limiting configuration 41ca limits the attachment surface of the cooling fan 8 in conformance with the shape of the cooling fan 8. As illustrated in FIG. 9, each cooling fan 8 according to the present embodiment is provided with a screw attachment portion 8d protruding in the radial direction of the cooling fan 8, on one of the side surfaces of the cooling fan 8. Each attachment-surface limiting configuration 41ca is a recess portion provided in the base-side air duct 41 so as to accommodate the screw attachment portion 8d when the correct attachment surface of the cooling fan 8 (the surface to be attached for causing cooling air generated from the cooling fan 8 to flow in the designed direction) is positioned on the base-side air duct 41. Therefore, in mounting the cooling fan 8 to the base-side air duct 41, by causing the screw attachment portion 8d to be accommodated in the attachment-surface limiting configuration 41ca, it is possible to mount the cooling fan 8 on the base-side air duct 41 in the correct orientation.

The cooling fans 8 are components (see FIG. 8) disposed downstream of the heat dissipation fins (the base-side heat dissipation fins 21a in the present embodiment) positioned in the downstream side of the cooling air flow path AD, out of the first heat dissipation fins and the second heat dissipation fins, for discharging cooling air CA toward the downstream side of the cooling air flow path AD.

The cooling fans 8 according to the present embodiment are fixed to the fan fixing portions 41c in the base-side air duct 41, and are electrically connected to the fan connectors 8a through cables 8c. The cooling fans 8 can be constituted by, for example, thin blower fans formed from an aluminum die cast or a resin frame. The fan fixing portions 41c can be easily formed in conformance with the shape of the cooling fan 8 to be fixed thereto. Therefore, it is possible to use general-purpose products as the cooling fans 8, thereby reducing the cost.

Preferably, the cooling fans 8 are a plurality of cooling fans 8 arranged in parallel with respect to the flow of cooling air CA and fixed to the air duct 4 (the plurality of the fan fixing portions 41c provided in the base-side air duct 41). Therefore, a plurality of the fan fixing portions 41c is provided in parallel with respect to the flow of cooling air.

The electronic control device 1 according to the present embodiment preferably includes a partition 41cb provided between two adjacent cooling fans 8, out of the plurality of cooling fans 8. For example, as illustrated in FIG. 9, the partition 41cb may be a plate-shaped protrusion protruding upward from the upper surface of the base-side air duct 41 between two adjacent fan fixing portions 41c and extending longer in the forward and rearward direction than the forward and rearward length of the cooling fans.

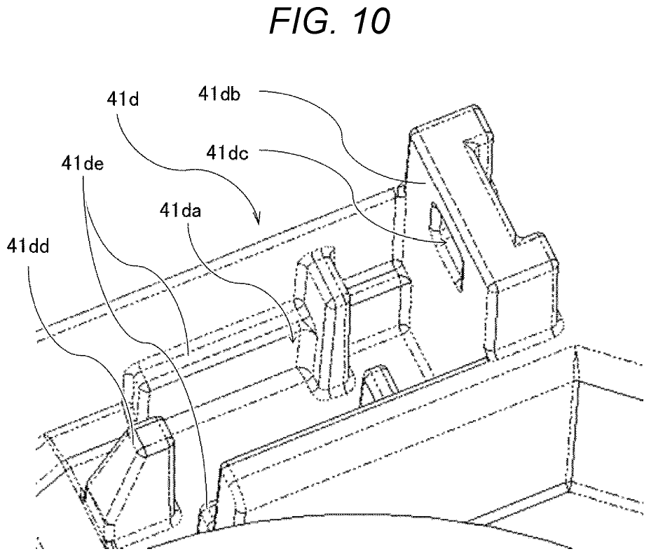

As illustrated in FIGS. 3 and 9, the base-side air duct 41 is provided with the connector fixing portions 41d for fixing the fan connectors 8a. FIG. 10 is an enlarged perspective view of a connector fixing portion 41d provided in the base-side air duct 41 according to the present embodiment.

As illustrated in FIG. 10, the connector fixing portion 41d is preferably provided with a groove portion 41da for inserting the fan connector 8a therein, a latch engagement portion 41db including a latch receiver 41dc, a boss 41dd for suppressing the fan connector 8a from moving in the direction away from the latch engagement portion 41db, and a pair of support portions 41de for supporting the fan connector 8a.

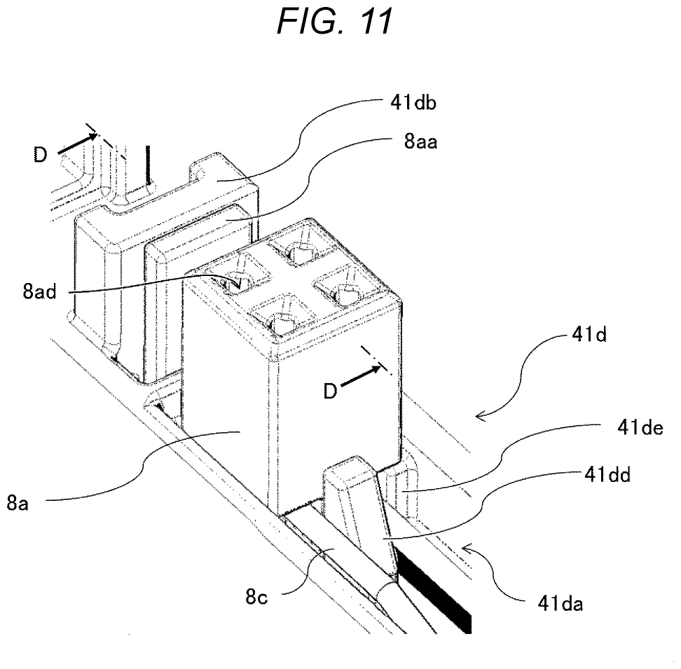

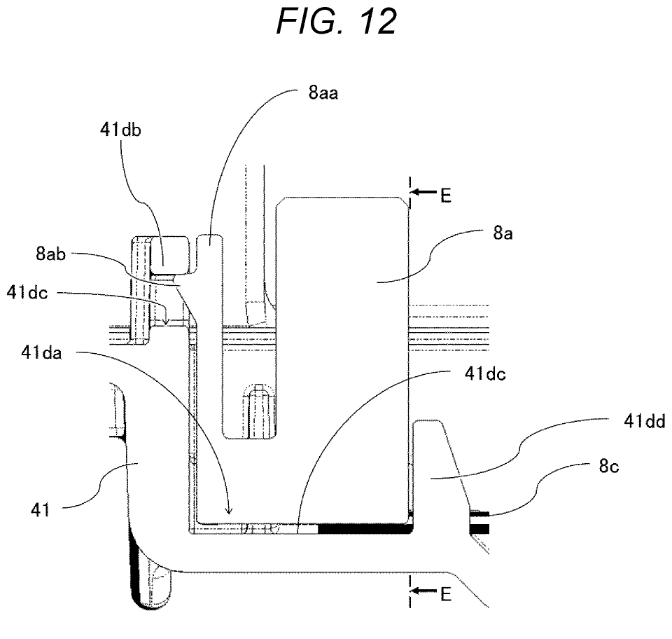

FIG. 11 is an enlarged perspective view of the fan connector 8a attached to the connector fixing portion 41d in the base-side air duct 41, and FIG. 12 is a cross-sectional view taken along a line D-D in FIG. 11, according to the first embodiment of the present invention. The D-D cross section passes through the center of the fan connector 8a.

As illustrated in FIG. 11, the fan connector 8a is such that its end surface having a plurality of openings 8ad is oriented upward, and its end surface for drawing the cables 8c therefrom is inserted into the groove portion 41da.

As illustrated in FIG. 12, the fan connector 8a is preferably provided with a latch locking portion 8aa, which is formed to have a leaf spring shape and is provided with a hook 8ab to engage with the latch receiver 41dc when the fan connector 8a is inserted in the groove portion 41da.

The latch locking portion 8aa and the latch engagement portion 41db form a latch mechanism. Preferably, the fan connector 8a inserted in the groove portion 41da in the connector fixing portion 41d and the base-side air duct 41 are coupled to each other through the latch mechanism.

It is preferable that the boss 41dd suppresses the fan connector 8a inserted in the groove portion 41da in the connector fixing portion 41d from moving in the direction away from the latch engagement portion 41db, thereby preventing the hook 8ab locked to the latch receiver 41dc from being disengaged from the latch receiver 41dc.

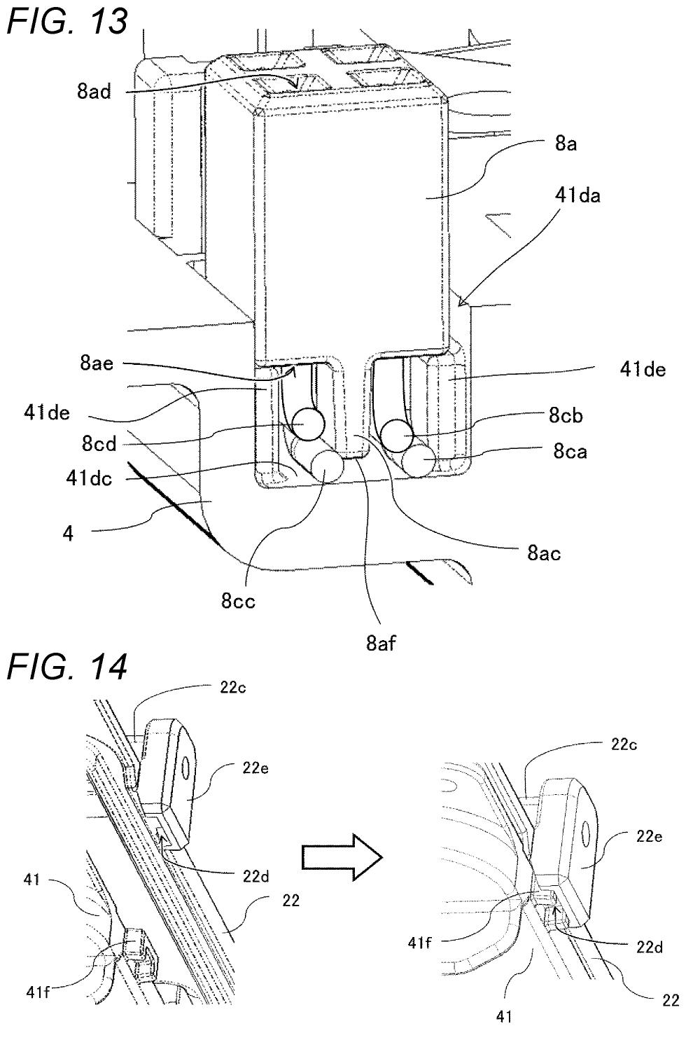

FIG. 13 is a cross-sectional perspective view taken along a line E-E in FIG. 12. As illustrated in FIG. 13, the fan connector 8a inserted in the groove portion 41da abuts on and is supported by the pair of support portions 41de in the connector fixing portion 41d.

Further, preferably, the fan connector 8a is provided, on its bottom surface 8ae to come in contact with the pair of support portions 41de (the surface of the fan connector 8a which is closer to the groove portion 41da), with a protruding portion 8ac protruding toward the bottom surface 41dc along the groove portion 41da.

Further, preferably, the plurality of cables 8c drawn out from the bottom surface 8ae is disposed along the groove portion 41da through the protruding portion 8ac. In the example of FIG. 13, four cables 8c (cables 8ca to 8cd) are drawn out from the bottom surface 8ae of the fan connector 8a, in which the cables 8cc and 8cd are disposed to the left of the protruding portion 8ac, and the cables 8ca and 8cb are disposed to the right thereof, along the groove portion 41da.

In order to dispose the plurality of cables 8c along the groove portion 41da through the protruding portion 8ac, and to certainly insert the hook 8ab into the latch receiver 41dc (see FIG. 1), there is provided a gap smaller than the diameter of the cable 8c between the tip end 8af of the protruding portion 8ac and the bottom surface 41dc of the groove portion 41da.

Since the gap is provided between the tip end 8af of the protruding portion 8ac and the bottom surface 41dc of the groove portion 41da, the fan connector 8a abuts on and is supported by the pair of support portions 41de in the connector fixing portion 41d.

On the other hand, if the fan connector 8a is inserted into the groove portion 41da without abutting on the pair of support portions 41de in the connector fixing portion 41d due to a manufacturing error or the like, the tip end 8af of the protruding portion 8ac abuts on the bottom surface 41dc of the groove portion 41da. This can suppress the cables 8c from being sandwiched between the bottom surface 8ae of the fan connector 8a and the bottom surface 41dc of the groove portion 41da.

The fan connector 8a is an electric component detachable from the power supply connector 6b, and is preferably fixed to the base-side air duct 41 and electrically connected to the power supply connector 6b, thereby feeding electricity to the cooling fan 8 through the cables 8c. The fan connector 8a is formed from a resin such as polybutylene terephthalate (PBT), polyamide (PA), or polyphenylene sulfide (PPS), and interiorly includes a plurality of female terminals mainly containing copper.

As illustrated in FIGS. 11 and 13, the fan connector 8a is provided, in its upper end surface, with a plurality of openings 8ad communicating with the plurality of female terminals, such that the cooling-fan-side terminals 6bb (see FIG. 6) in the power supply connector 6b can be inserted in the plurality of female terminals inside thereof. A cable 8c is electrically connected to each of the plurality of female terminals, and is drawn out from the other end surface of the fan connector 8a.

Since the connector fixing portions 41d in the base-side air duct 41 can be easily formed in conformance with the shape of the fan connector 8a to be fixed thereto, it is possible to use general-purpose products as the fan connectors 8a, thereby reducing the cost.

Further, the base-side air duct 41 is preferably provided with the cable storage portions 41e for storing the extra lengths of the cables 8c, as illustrated in FIG. 9. This makes it easier to store the extra length portions of the cables 8c, thereby improving the work efficiency. Further, in attaching a subassembly 48 to the housing 2, it is possible to prevent the cables 8c from being sandwiched between the base-side air duct 41 and the housing 2, which prevents the cables 8c from being damaged.

The cables 8c are electric wires for electrically connecting the cooling fans 8 and the fan connectors 8a to each other. The cables 8c are preferably longer than the distance (linear distance) between the portion of the cooling fan 8 to which the cables 8c are connected and the portion of the fan connector 8a to which the cables 8c are connected (namely, the cables 8c are preferably provided with an extra length portion), and the cables 8c are placed in such a way as to curve the wiring path in a substantially U shape, for example. In consideration of the aforementioned point and a standard size of an electronic control device for a vehicle, it is preferable that the cables 8c have a length of 5 cm to 15 cm. Since the base-side air duct 41 is provided with the cable storage portions 41e, the extra length portions of the cables 8c are stored in the cable storage portions 41e.

In order to provide a plurality of cooling fans 8 (two cooling fans 8 in the present embodiment), it is preferable to provide the same number of connector fixing portions 41d and the same number of cable storage portions 41e as the number of cooling fans 8. Further, the electronic control device 1 preferably includes a potting material applied to the portions where the fan connector 8a and the cables 8c are electrically connected to each other. The cooling fans 8 are preferably waterproof cooling fans. This can make the electronic control device 1 be of a waterproof specification. Incidentally, it is possible to select waterproof and dustproof specifications for the electronic control device 1, through use or non-use of the sealing material 7, the potting material, and the waterproof cooling fans, which enables changing over the specifications depending on the location where the electronic control device 1 is to be installed.

Preferably, the electronic control device 1 according to the present embodiment further includes a temperature sensor, and the rotational speed of the cooling fans 8 is controlled based on a value detected by the temperature sensor. For example, it is preferable to provide a temperature sensor incorporated in the electronic components 6a, and the rotational speed of the cooling fans 8 is controlled based on a value detected by the temperature sensor incorporated in the electronic components 6a (that is, a temperature around the electronic components 6a). Also, a temperature sensor may be mounted on the circuit board 6, and the rotational speed of the cooling fans 8 may be controlled based on a value detected by the temperature sensor (that is, a temperature around the temperature sensor mounted on the circuit board 6).

Preferably, the cables 8c are a plurality of cables 8c, and the plurality of cables 8c include a cable 8cc for transmitting a rotational-speed command (for example, a PWM signal) for the cooling fans 8, and a cable 8cd for transmitting a detection signal from a rotational speed sensor attached to the cooling fans 8.

Specifically, it is preferable that the plurality of cables 8c include four cables 8c (a positive wire (red) 8ca, a negative wire (black) 8cb, a PWM wire (blue) 8cc, and a pulse wire (yellow) 8cd), as illustrated in FIG. 13. The positive wire (red) 8ca and the negative wire (black) 8cb are cables 8c for feeding an electric current to the cooling fans 8.

Further, since the cooling fans 8 are blower fans, air exhaust ports 41cc for exhausting cooling air from the cooling fans 8 are preferably provided in the front side of the fan fixing portions 41c for fixing the cooling fans 8, as illustrated in FIGS. 3, 8, and 9.

As illustrated in FIG. 4, the base-side air duct 41 is provided, on its left and right side surfaces, with a plurality of positioning male portions 41f. FIG. 14 is partial perspective views illustrating the electronic control device 1 according to the first embodiment of the present invention, in states before and after attaching the positioning male portions 41f in the base-side air duct 41 to the positioning female portions 22d in the cover 22.

As illustrated in FIG. 14, in attaching the base-side air duct 41 to the housing 2, the positioning male portions 41f are fitted into the positioning female portions 22d provided in the lower surfaces of the protrusions 22e provided on the left and right side surfaces of the cover 22. As a result, the base-side air duct 41 is positioned at a predetermined position with respect to the housing 2.

Namely, the electronic control device 1 according to the present embodiment is preferably provided with the positioning female portions 22d and the positioning male portions 41f as an attachment position limiting configuration for limiting the position at which the cover 22 and the base-side air duct 41 are attached to each other.

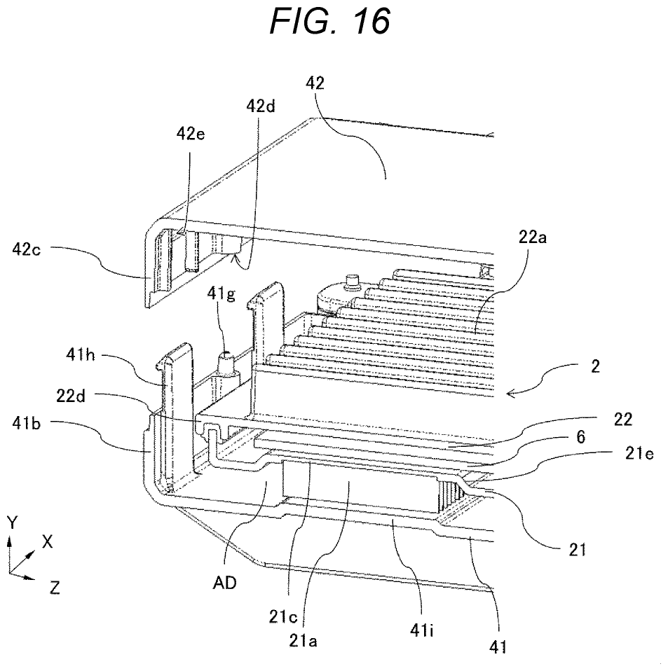

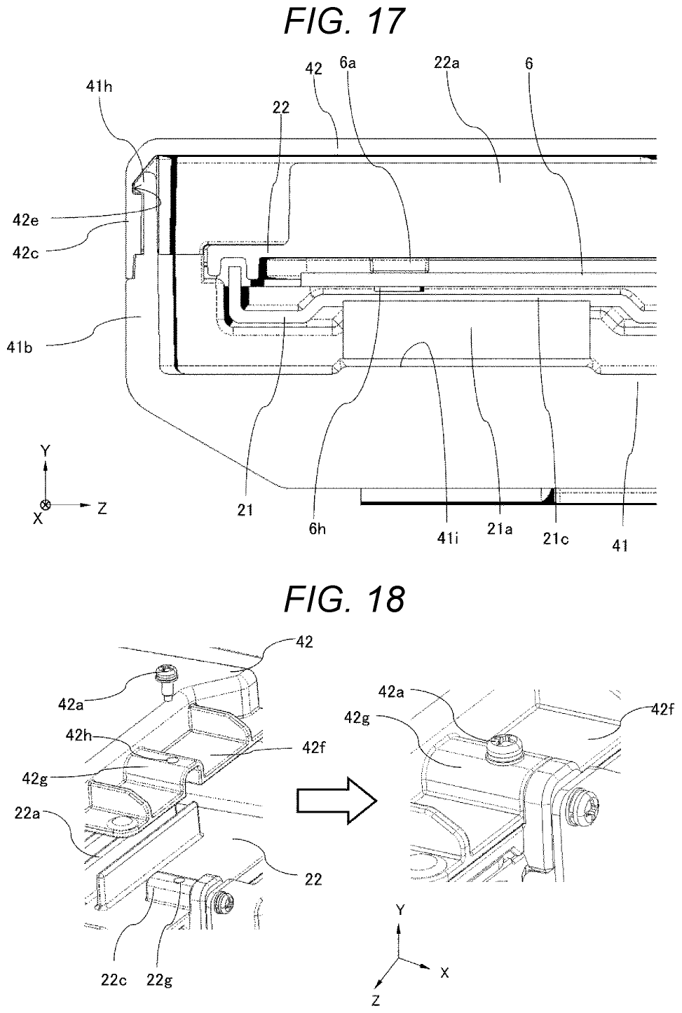

FIG. 15 is a perspective view of the housing 2 and the subassembly 48 in the electronic control device according to the first embodiment of the present invention. FIG. 16 is a partial cross-sectional perspective view of the rear sides of the housing 2 and the cover 22 to which the subassembly 48 is attached, in the electronic control device 1 according to the first embodiment of the present invention. FIG. 17 is a cross-sectional view taken along a line F-F in FIG. 2.

As illustrated in FIG. 15, the subassembly 48 is constituted by the base-side air duct 41 integrated with the cooling fans 8 and the fan connectors 8a attached and secured thereto. By attaching the subassembly 48 to the lower surface of the base 21, the fan connectors 8a are electrically connected to the power supply connectors 6b, and the cooling air flow path AD is formed between the base 21 and the base-side air duct 41, as illustrated in FIG. 16.

Preferably, the base-side air duct 41 is provided with positioning bosses 41g for positioning the cover-side air duct 42 on an upper portion of the rear wall 41b thereof, and further is provided with latch locking portions 41h having a leaf spring shape for locking the cover-side air duct 42, as illustrated in FIG. 16.

Further, preferably, a rear wall 42c is provided, in its lower end, with boss holes 42d to be fitted on the positioning bosses 41g in the base-side air duct 41, and with latch engagement portions 42e to be locked by the latch locking portions 41h in the base-side air duct 41.

By inserting the positioning bosses 41g into the boss holes 42d, the rear wall 42c of the cover-side air duct 42 can be positioned with respect to the rear wall 41b of the base-side air duct 41. Further, by inserting the latch locking portions 41h in the base-side air duct 41 into the latch engagement portions 42e, the rear wall 42c of the cover-side air duct 42 and the rear wall 41b of the base-side air duct 41 can be engaged with each other, as illustrated in FIG. 17.

As illustrated in FIG. 8, the cover-side air duct 42 is a component attached to the housing 2 so as to cover the cover-side heat dissipation fins 22a (the second heat dissipation fins) provided on the upper surface of the cover 22, thereby forming the cooling air flow path AD on the upper surface of the housing 2. The cover-side air duct 42 is secured to the housing 2 through screws 42a (see FIG. 3).

As illustrated in FIGS. 3 and 8, there is provided an air intake port 42b for taking in cooling air CA, in front of the cover-side air duct 42 (behind the cover 22 covering the external connection connector 3). The rear wall 42c in the rear side (in the opposite side from the air intake port 42b) of the cover-side air duct 42 is formed so as to be separated from the rear end portion 22f of the cover 22, as illustrated in FIG. 8. This forms a gap GP4 for flowing cooling air CA therethrough, between the rear wall 42c and the rear end portion 22f.

As illustrated in FIG. 8, the cooling air flow path AD structured as described above is formed as a single flow path without branching, through a portion from the first heat dissipation fins up to the second heat dissipation fins.

It is preferable that a gap GP5 is formed between the cover-side air duct 42 attached to the housing 2 and the tip ends 22ab of the plurality of protrusions 22aa included in the cover-side heat dissipation fins 22a, as illustrated in FIG. 5.

Preferably, the dimension of the gap GP5 is set such that the flow rate of cooling air passing through the gap GP5 is smaller than the flow rate of cooling air passing through an interval GP6 between two adjacent protrusions 22aa out of the plurality of protrusions 22aa included in the cover-side heat dissipation fins 22a.

Here, preferably, in the cooling air flow path AD, out of the two portions provided with the first heat dissipation fins and the second heat dissipation fins, at least one portion has a flow path cross-sectional area smaller than the flow path cross-sectional area of the portion upstream of the at least one portion.

For example, as illustrated in FIG. 8, the portion (fin facing portion 41i) of the base-side air duct 41 which faces the base-side heat dissipation fins 21a may be raised toward the base-side heat dissipation fins 21a (upward), thereby providing a level difference 41j upstream (rearward) of the fin facing portion 41i. Consequently, in the fin facing portion 41i, the cooling air flow path AD has a longitudinal width W1 narrower than the longitudinal width W2 in the portion upstream thereof. When the cooling air flow path AD has a constant lateral width, the cooling air flow path AD has a smaller flow path cross-sectional area in the fin facing portion 41i in the flow path than the flow path cross-sectional area in the portion upstream thereof. As a result, cooling air CA flows through the portion provided with the base-side heat dissipation fins 21a at a larger flow velocity than the flow velocity of cooling air CA flowing through the portion upstream thereof, thereby improving the cooling performance.

Further, in the cooling air flow path AD, it is preferable to form, through skiving, the heat dissipation fins provided in at least one portion having a flow path cross-sectional area smaller than the flow path cross-sectional area of the portion upstream thereof, out of the two portions provided with the first heat dissipation fins and the second heat dissipation fins. For example, as illustrated in FIG. 8, it is possible to form, through skiving, the base-side heat dissipation fins 21a facing the fin facing portion 41i with a flow path cross-sectional area smaller than that of the portion upstream thereof.

FIG. 18 is partial perspective views illustrating the electronic control device 1 according to the present embodiment, in states before and after attaching the positioning female portions 42g in the cover-side air duct 42 to the positioning male portions 22c in the cover 22. Although FIG. 18 illustrates only the right side, the cover 22 and the cover-side air duct 42 are bilaterally symmetrical, and the left side thereof has the same structure.

Preferably, the cover-side air duct 42 is provided, in its left and right ends, with flange portions 42f extending outward in the leftward and rightward directions from the cover-side air duct 42 and each having a lower surface covering the upper surface of the cover 22, as illustrated in FIG. 18.

Preferably, the pair of flange portions 42f is each provided with a half-cylindrical positioning female portion 42g having a central axis placed in the leftward and rightward direction and having an inner surface faced to the cover 22. When the cover-side air duct 42 is attached to the cover 22, the positioning female portions 42g are fitted onto the positioning male portions 22c provided in the cover 22. As a result, in the electronic control device 1 according to the present embodiment, the cover-side air duct 42 can be easily positioned with respect to the positioning female portions 42g.

Namely, the electronic control device 1 according to the present embodiment is preferably provided with the positioning male portions 22c and the positioning female portions 42g as an attachment position limiting configuration for limiting the position at which the cover 22 and the cover-side air duct 42 are attached to each other.

The positioning female portions 42g are provided with a through hole 42h vertically penetrating the cylindrical wall. Further, each positioning male portion 22c is provided with a screw hole 22g in its the upper surface. By inserting the screws 42a into the through holes 42h and tightening the screws 42a in the screw holes 22g, the cover-side air duct 42 is secured to the cover 22.

The device-side brackets 5 are components for securing the electronic control device 1 to the vehicle, and are attached to the housing 2 through screws 5a as illustrated in FIG. 1. Also, the device-side brackets 5 may be formed integrally with the housing 2.

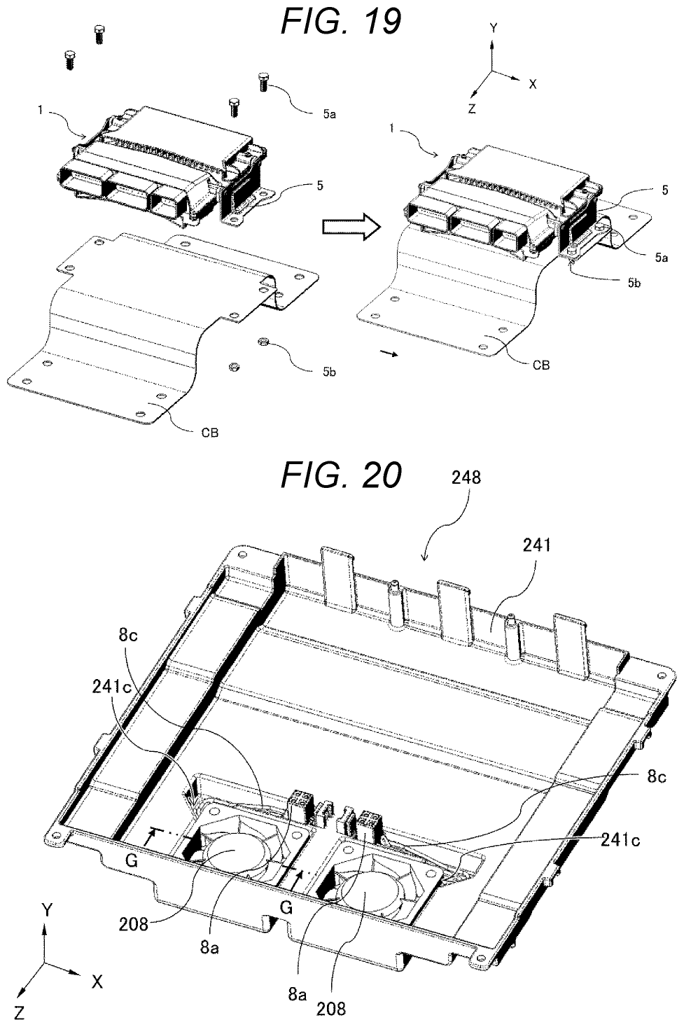

FIG. 19 is partial perspective views illustrating the electronic control device 1 according to the first embodiment of the present invention, in states before and after being attached to a vehicle-side bracket CB. As illustrated in FIG. 19, the electronic control device 1 is attached to the vehicle-side bracket CB with the device-side brackets 5 interposed therebetween, through the screws 5a and nuts 5b. At this time, the cooling fans 8 are preferably secured to the vehicle so as to be positioned closer to the vehicle than to the housing 2. Therefore, the device-side brackets 5 are attached to the housing 2 such that the base-side air duct 41 having the cooling fans 8 secured thereto is positioned closer to the vehicle.

### Effects

An electronic control device 1 according to the present embodiment includes: a circuit board 6 having a plurality of electronic components 6a mounted thereon; a housing 2 adapted to seal and house the circuit board 6; first heat dissipation fins constituted by a plurality of protrusions provided on a lower surface of the housing 2; second heat dissipation fins constituted by a plurality of protrusions provided on an upper surface of the housing 2; an air duct 4 attached to an outer side of the housing 2 so as to cover the first heat dissipation fins and the second heat dissipation fins and adapted to form a cooling air flow path AD for flowing cooling air CA therethrough near the upper surface and the lower surface of the housing 2; and cooling fans 8 installed downstream of the heat dissipation fins positioned in a downstream side of the cooling air flow path AD, out of the first heat dissipation fins and the second heat dissipation fins, and adapted to exhaust cooling air CA toward a downstream side of the cooling air flow path AD, in which the cooling air flow path AD is formed to be a single flow path without branching, through a portion from the first heat dissipation fins up to the second heat dissipation fins.

In the present embodiment, the cooling air flow path AD is formed to be a single flow path without branching, through the portion from the first heat dissipation fins up to the second heat dissipation fins. Accordingly, the cooling air flow path AD can be regarded as having a flow path configuration with two flow-path resistances arranged in series on one cooling air flow path AD. Therefore, the total air volume can be easily calculated from the sum of the flow-path resistances of the first heat dissipation fins and the second heat dissipation fins. This makes it easier to implement cooling design. Further, the first heat dissipation fins and the second heat dissipation fins are disposed on the single cooling air flow path AD, and the actual value of the air volume is close to a theoretical value, which also lowers the difficulty of designing.

Namely, according to the present embodiment, it is possible to easily secure a required air volume in the entire flow path, and it is possible to easily implement balance design in such a way as to flow a required air volume through a portion which requires the air volume. This can also simplify the design of the housing.

Furthermore, the present embodiment employs a configuration which provides the first heat dissipation fins on the lower surface of the housing 2 and provides the second heat dissipation fins on the upper surface of the housing, thereby cooling both the upper and lower surfaces of the housing through the first heat dissipation fins and the second heat dissipation fins. The cooling fans 8 are installed downstream of the heat dissipation fins positioned in a downstream side, out of the first and second heat dissipation fins. This enables certainly flowing cooling air CA through the first and second heat dissipation fins, thereby effectively cooling the upper and lower surfaces of the housing 2.

Further, preferably, in the cooling air flow path AD, out of the two portions provided with the first heat dissipation fins and the second heat dissipation fins, at least one portion has a flow path cross-sectional area smaller than the flow path cross-sectional area of the portion upstream of the at least one portion. Accordingly, in the portion having the smaller flow path cross-sectional area, cooling air is made to have a larger flow velocity than that in the portion upstream thereof. This causes cooling air to pass through the heat dissipation fins in the portion having the smaller flow path cross-sectional area at a larger flow velocity, thereby improving the cooling performance.

Further, it is preferable to form, through skiving, at least the heat dissipation fins provided in the portion having the smaller flow path cross-sectional area, which are the first heat dissipation fins or the second heat dissipation fins. This enables narrowing the pitch of the plurality of protrusions in the heat dissipation fins in the portion adapted to increase the flow velocity of cooling air, thereby increasing the heat dissipation area and thinning the plurality of protrusions to reduce the pressure loss. This can further improve the cooling efficiency.

Preferably, the cooling fans 8 are a plurality of cooling fans 8 fixed to the air duct 4 and arranged in parallel with respect to the flow of cooling air CA. Accordingly, even if one of the plurality of cooling fans 8 is stopped, cooling air CA can be continuously flowed through the cooling air flow path AD by the other cooling fans 8. Since the plurality of cooling fans 8 are fixed to the air duct 4, the plurality of cooling fans 8 can be easily detached from the housing by detaching the air duct 4 from the housing 2.

Further, wind noises predominate in noises from the cooling fans 8, and an increase of the rotational speed thereof greatly affects noise values. Therefore, for example, by outputting a required air volume from two cooling fans 8, rather than from a single cooling fan 8, it is possible to reduce the noise value. Therefore, with the electronic control device 1 according to the present embodiment, which includes the plurality of cooling fans 8, it is possible to reduce noises.

Further, the power consumption of the cooling fans 8 is proportional to the cube of the rotational speed of the cooling fans 8. Therefore, an increase of the rotational speed thereof greatly affects the power consumption. Therefore, for example, by outputting a required air volume from two cooling fans 8, rather than from a single cooling fan 8, it is possible to reduce the power consumption. Therefore, with the electronic control device 1 according to the present embodiment, it is possible to attain power saving, since it includes the plurality of cooling fans 8.

Further, the electronic control device 1 according to the present embodiment includes the partition 41cb between two adjacent cooling fans 8 out of the plurality of cooling fans 8 arranged in parallel with respect to the flow of cooling air CA. Therefore, in the event of a failure of any one of the plurality of cooling fans 8, it is possible to suppress outside air from flowing into the cooling fans 8 being operated from the stopped cooling fan 8, which suppresses the degradation of the cooling capacity.

Further, the electronic control device 1 according to the present embodiment further includes a temperature sensor, inside the electronic components 6a, for example, and the rotational speed of the cooling fans 8 is controlled based on a value detected by the temperature sensor. This enables controlling the rotational speed of the cooling fans 8 according to the temperature of the electronic components 6a, which enables appropriately supplying a necessary air volume for cooling the electronic components 6a to a predetermined temperature. This can attain power saving and noise reduction in the cooling fans 8, and extension of the life of the cooling fans 8.

In the electronic control device 1 according to the present embodiment, the circuit board 6 and the cooling fans 8 are electrically connected to each other through the cables 8c, the fan connectors 8a, and the power supply connectors 6b. Therefore, vibrations of the cooling fans 8 are not directly transmitted to the circuit board 6. This suppresses occurrences of contact failures in the electric connection portions between the cooling fans 8 and the circuit board 6 due to fretting corrosion, which can improve the reliability of the electrical connections between the cooling fans 8 and the circuit board 6.

The fan connectors 8a are detachably connected to the power supply connectors 6b, and the cooling fans 8 and the fan connectors 8a are secured to the base-side air duct 41 to form the subassembly 48. Therefore, it is possible to mount the cooling fans 8 on the electronic control device 1, by attaching the subassembly 48 to the housing 2 and electrically connecting the power supply connectors 6b and the fan connectors 8a to each other. This can simplify the process for mounting the cooling fans 8 on the electronic control device 1, thereby improving the work efficiency.

In the electronic control device 1 according to the present embodiment, the cooling fans 8 are secured to the vehicle so as to be positioned closer to the vehicle than the housing 2. This can intercept noises from the cooling fans 8 by the housing 2, thereby attaining noise reduction. Further, even in the event that a foreign substance such as a pebble comes flying toward the electronic control device 1, since the cooling fans 8 are shielded by the housing 2, the foreign substance is hindered from directly impinging on the blades of the cooling fans.

In the electronic control device 1 according to the present embodiment, the plurality of electronic components 6a are arranged in parallel with respect to the direction of flow of cooling air CA. Therefore, cooling air for cooling the respective plural electronic components 6a flows in parallel, which suppresses cooling air from flowing through each of the plurality of electronic components 6a after having been increased in temperature by other electronic components 6a. This can improve the efficiency of cooling the electronic component 6a.

Further, the electronic control device 1 according to the present embodiment preferably includes a gap GP1 or GP5 between the air duct 4 and the tip ends 21ab or 22ab of the first heat dissipation fins or the second heat dissipation fins. This can suppress the tip ends 21ab or 22ab of the first heat dissipation fins or the second heat dissipation fins from bumping against the air duct 4 due to an assembly error or the like, which can suppress deformation of the first heat dissipation fins or the second heat dissipation fins.

In the electronic control device 1 according to the present embodiment, preferably, the dimension GP2 or GP6 between two adjacent protrusions out of the plurality of protrusions included in the first heat dissipation fins or the second heat dissipation fins is set such that the flow rate of cooling air CA passing between the air duct 4 and the tip ends 21ab or 22ab of the plurality of heat dissipation fins is smaller than the flow rate of cooling air CA passing between two adjacent protrusions out of the plurality of protrusions included in the first heat dissipation fins or the second heat dissipation fins. This can decrease the amount of cooling air CA passing through the gap between the air duct 4 and the tip ends 21ab or 22ab of the first heat dissipation fins or the second heat dissipation fins, which does not contribute to cooling. On the other hand, it is possible to increase the amount of cooling air CA passing between two adjacent protrusions out of the plurality of protrusions included in the first heat dissipation fins or the second heat dissipation fins, which contributes to cooling. Consequently, it is possible to improve the cooling efficiency.

In the electronic control device 1 according to the present embodiment, the plurality of electronic components 6a are in contact with the housing 2 with the heat dissipation grease 6h interposed therebetween, which enables efficiently cooling the plurality of electronic components 6a, thereby improving the cooling performance.

In the electronic control device 1 according to the present embodiment, the housing 2 and the air duct 4 are provided with an attachment-position limiting configuration for limiting the position at which the housing 2 and the air duct 4 are attached to each other (the positioning female portions 22d, the positioning male portions 41f, the positioning male portions 22c, and the positioning female portions 42g). This enables defining the position at which the housing 2 and the air duct 4 are attached to each other through the attachment-position limiting configuration, in assembling the housing 2 and the air duct 4 to each other, which can suppress failures of the couplings between the fan connectors 8a and the power supply connectors 6b, sandwiching of the cables 8c between the housing 2 and the air duct 4, and the like.

The air duct 4 (the base-side air duct 41) according to the present embodiment is provided with the attachment-surface limiting configuration 41ca for limiting the attachment surfaces of the cooling fans 8 in conformance with the shape of the cooling fans 8. This prevents the cooling fans 8 from being mounted on the base-side air duct 41 at wrong attachment surfaces of the cooling fans 8. This can reduce the labor for mounting the cooling fans on the air duct, and can suppress occurrence of product defects.

In the electronic control device 1 according to the present embodiment, it is preferable that the air duct 4 is provided with cable storage portions 41e for storing the cables 8c. This makes it easier to store the extra length portions of the cables 8c, thereby improving the work efficiency. Further, in attaching the subassembly 48 to the housing 2, it is possible to prevent the cables 8c from being sandwiched between the housing 2 and the air duct 4, which prevents the cables 8c from being damaged.

In the electronic control device 1 according to the present embodiment, the power supply connectors 6b are preferably attached to the circuit board 6. This enables coupling the power supply connectors 6b and the circuit board 6 to each other at a shortest distance, which can improve the reliability of the electrical connection therebetween. In the electronic control device 1 according to the present embodiment, preferably, the power supply connectors 6b are inserted into the through holes 21b provided in the housing 2 (the base 21), and the second sealing material 7b is provided in the gap formed between each through hole 21b and (the plate-shaped portion 6bc of) each power supply connector 6b. This enables sealing the intervals between the through holes 21b in the base 21 and the plate-shaped portions 6bc by the second sealing materials 7b, thereby realizing a configuration for sealing the housing 2.

In the electronic control device 1 according to the present embodiment, preferably, each fan connector 8a and the air duct 4 are provided with a latch mechanism (the latch locking portion 8aa and the latch engagement portion 41db) for coupling the fan connector 8a and the air duct 4 to each other. This enables easily assembling and securing the fan connectors 8a to the air duct 4, thereby improving the work efficiency.

### Second Embodiment

FIG. 20 is a perspective view of a subassembly 248 according to a second embodiment of the present invention. The subassembly 248 according to the present embodiment is different from the subassembly 48 according to the first embodiment, in that axial fans 208 are used as cooling fans, and air exhaust ports 241cc are provided in the bottom surfaces of cooling fan fixing portions 241c in a base-side air duct 241.

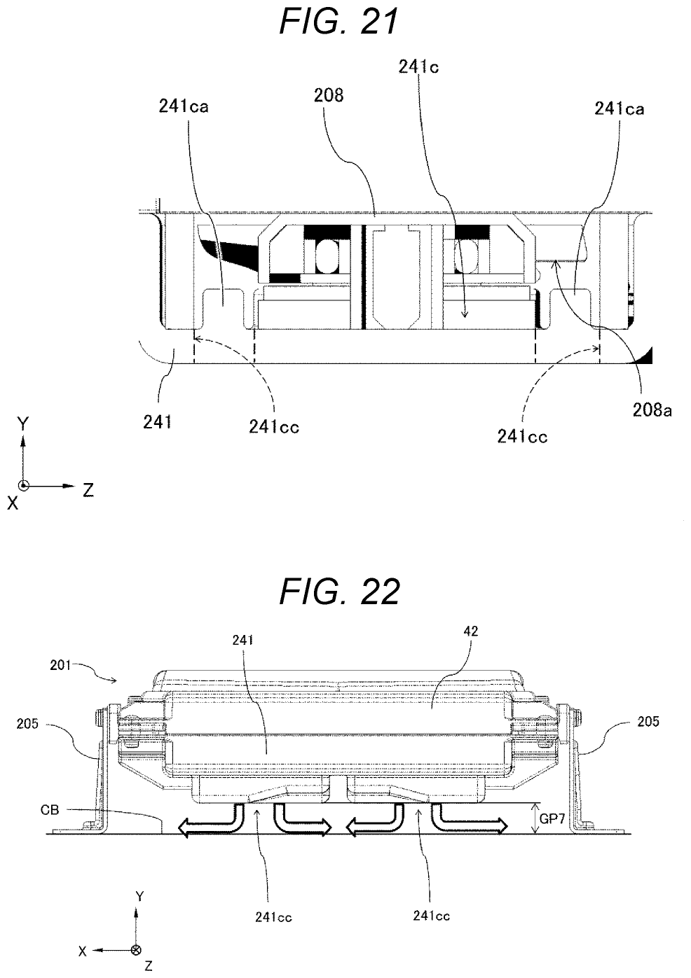

FIG. 21 is a cross-sectional view taken along a line G-G in FIG. 20. As illustrated in FIG. 21, it is preferable that the axial fans 208 are fixed to the cooling fan fixing portions 241c in the base-side air duct 241 according to the second embodiment of the present invention, and the air exhaust ports 241cc cc are provided below the axial fans 208.

The cooling fan fixing portions 241c in the base-side air duct 241 according to the second embodiment of the present invention is preferably provided with an attachment-surface limiting configuration for limiting the attachment surfaces of the axial fans 208. The attachment-surface limiting configuration according to the present embodiment is constituted by bosses 241ca protruding from the bottom surfaces of the cooling fan fixing portions 241c up to the vicinity of the lower ends 208a of the blades of the axial fans 208.

FIG. 22 is a rear view of an electronic control device 201 according to the second embodiment of the present invention. In the electronic control device 201 according to the present embodiment, it is preferable that the cooling fans are the axial fans 208, and device-side brackets 205 for attaching the electronic control device 201 to an object to which the electronic control device 201 is to be attached are adapted to maintain the interval between the air exhaust ports 241cc in the base-side air duct 241 and the object to which the electronic control device 201 is to be attached, at a predetermined value. For example, as illustrated in FIG. 22, the device-side brackets 205 maintain a distance GP7 between the air exhaust ports 241cc in the base-side air duct 241 and a vehicle-side bracket CB to which the electronic control device 201 is to be attached, at a predetermined value, which is about 15 mm or more, for example.

### Effects

In the electronic control device 201 according to the present embodiment, the cooling fans are the axial fans 208. This can make the air volume of cooling air larger than that of when blower fans are used as the cooling fans, which can improve the cooling performance.

In the electronic control device 201 according to the present embodiment, it is preferable that the cooling fans are the axial fans 208, and there are provided the device-side brackets 205 for attaching the electronic control device 201 to an object to which the electronic control device 201 is to be attached, and the device-side brackets 205 are adapted to maintain the interval CB between the air exhaust ports 241cc in the air duct 204 and the object to which the electronic control device 201 is to be attached at a predetermined value (such an interval as not to intercept exhausted air from the axial fans 208, which is 15 mm or more, for example). This can provide an interval which does not intercept exhausted air from the axial fans 208 between the air exhaust ports for the axial fans 208 and the object to which the electronic control device 201 is to be attached, which can suppress the idling phenomenon of the axial fans.

The base-side air duct 241 according to the present embodiment is provided with the bosses 241ca as an attachment-surface limiting configuration. Thus, if the axial fans 208 are attached to the base-side air duct 241 at wrong attachment surfaces thereof, the bosses 241ca interfere with the blades of the axial fans 208, which prevents the axial fans 208 from rotating. This can suppress the axial fans 208 from being attached to the base-side air duct 241 at wrong attachment surfaces thereof, which can reduce the labor for attaching the axial fans 208 to the base-side air duct 241, and also can suppress occurrence of product defects.

### Third Embodiment

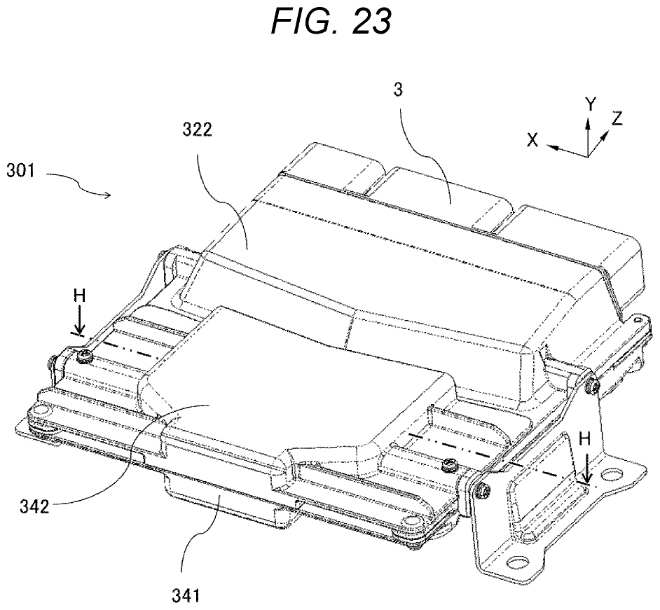

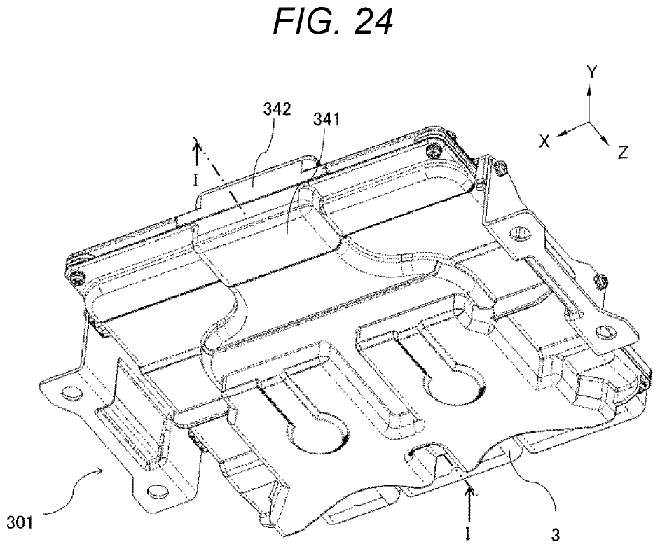

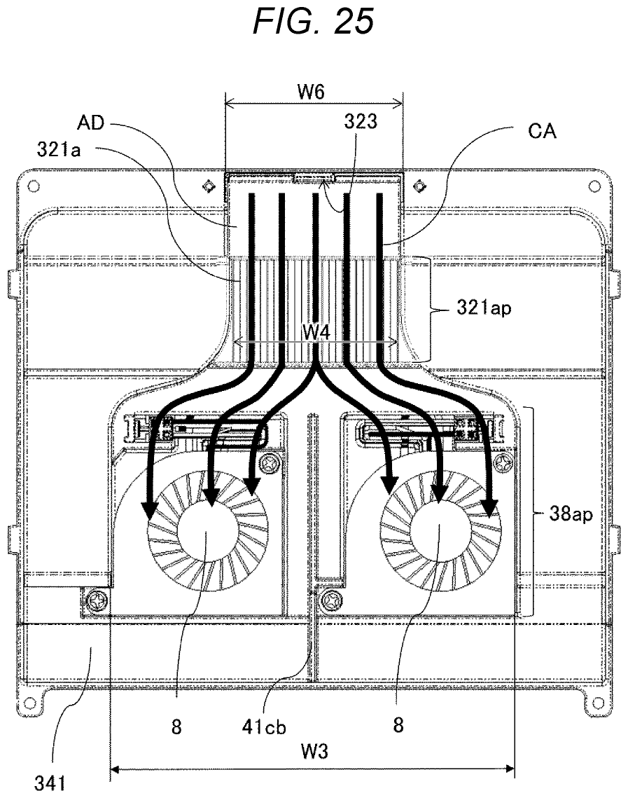

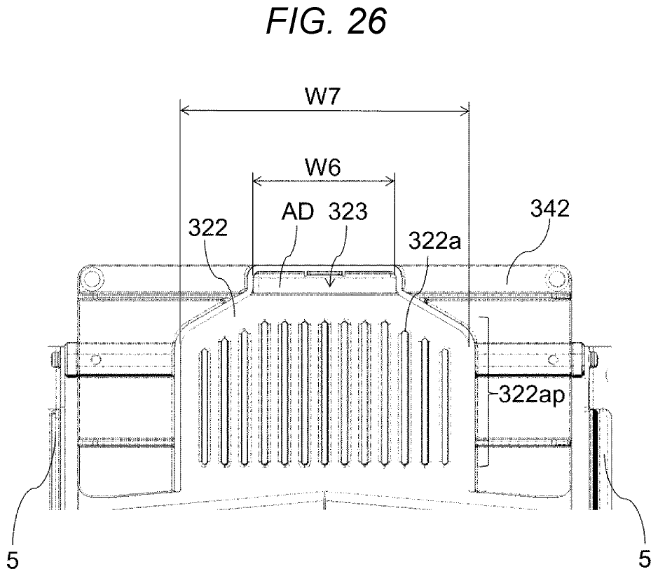

FIG. 23 is a perspective view of an electronic control device 301 according to the third embodiment of the present invention, as viewed from the left thereof, thereabove and therebehind (from above the back side of an external connection connector 3). FIG. 24 is a perspective view of the electronic control device 301 according to the third embodiment of the present invention, as viewed from the left thereof, therebelow and therebehind (from below the back side of the external connection connector 3). FIG. 25 is a cross-sectional view taken along a line I-I in FIG. 24. FIG. 26 is a cross-sectional view taken along a line H-H in FIG. 23.

The electronic control device 301 according to the present embodiment is different from the electronic control device 1 according to the first embodiment in that, in a cooling air flow path AD, the portion provided with a plurality of cooling fans 8 has a larger flow path width than the flow path width of the portion provided with heat dissipation fins positioned upstream of the cooling fans, out of first heat dissipation fins and second heat dissipation fins.

For example, preferably, the portion 308ap provided with the plurality of cooling fans 8 (two cooling fans 8 in the present embodiment) has a flow path width W3, which is larger than the flow path width W4 of the portion 321ap provided with the base-side heat dissipation fins 321a, as illustrated in FIG. 25.

Namely, in the electronic control device 301 according to the present embodiment, the flow path width W4 of the portion 321ap provided with the base-side heat dissipation fins 321a is smaller than the flow path width W3 of the portion 308ap provided with the plurality of cooling fans 8 (two cooling fans 8 in the present embodiment). On the other hand, as illustrated in FIG. 15, the portion provided with the base-side heat dissipation fins 21a according to the first embodiment has a flow path width W5, which is substantially the same as the flow path width W3 of the portion provided with the cooling fans 8. Therefore, the flow path width W4 of the portion 321ap provided with the base-side heat dissipation fins 321a according to the present embodiment is smaller than the flow path width W5 of the portion provided with the base-side heat dissipation fins 21a according to the first embodiment.

Similarly to in the first embodiment, it is preferable that a partition 41cb is provided between two adjacent cooling fans 8 out of the plurality of cooling fans 8.

Further, preferably, a communication flow path portion 323, at which the cooling air flow path AD in the base-side air duct 341 and the cooling air flow path AD in the cover-side air duct 342 communicate with each other, has a flow path width W6 substantially the same as the flow path width W4 of the portion provided with the base-side heat dissipation fins 321a, as illustrated in FIGS. 25 and 26.

Further, preferably, the portion downstream of the portion 322ap provided with the cover-side heat dissipation fins 322a is gradually narrowed from a flow path width W7 of the portion 322ap provided with the cover-side heat dissipation fins 322a to the flow path width W6 of the communication flow path portion 323, as illustrated in FIG. 26.

### Effects

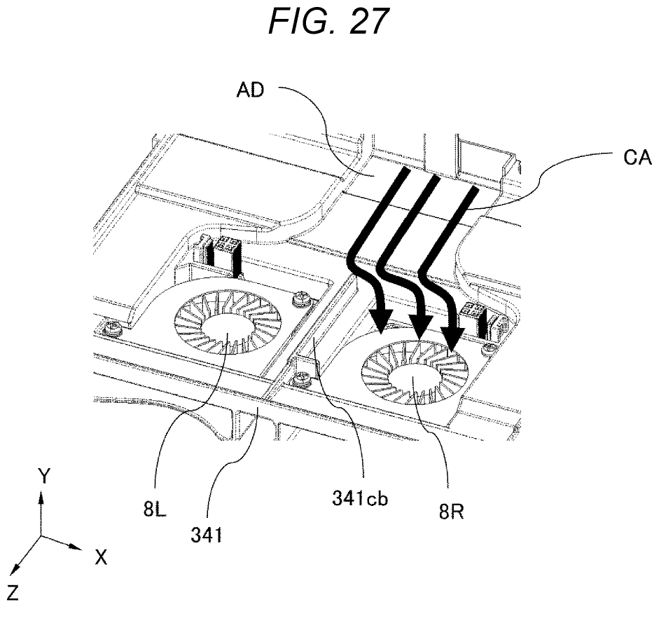

FIG. 27 is a perspective view illustrating a direction of cooling air CA flowing through the cooling air flow path AD formed in the base-side air duct 341, in the event of stop of one cooling fan (the left cooling fan 8L), out of the two cooling fans 8 included in the electronic control device 301 according to the third embodiment of the present invention.

As illustrated in FIG. 27, if the left cooling fan 8L out of the two cooling fans 8 is stopped, cooling air CA flows as illustrated in FIG. 27. Namely, in the electronic control device 301 according to the present embodiment, the flow path width W4 of the portion 321ap provided with the heat dissipation fins (the base-side heat dissipation fins 321a in the present embodiment) positioned in a downstream side of the cooling air flow path AD is smaller than the flow path width W3 of the portion provided with the plurality of cooling fans 8 (two cooling fans 8 in the present embodiment) (see FIG. 25). Therefore, the flow path width W4 in the present embodiment is smaller than the flow path width W5 (see FIG. 15) in the first embodiment, which can reduce variations in the flow velocity of cooling air flowing through the portion provided with the heat dissipation fins positioned in the downstream side of the cooling air flow path AD, as compared with the electronic control device 1 according to the first embodiment. This can alleviate the influence of stoppage of any one of the plurality of cooling fans 8, as compared with the electronic control device 1 according to the first embodiment.

In addition, since the partition 41cb is provided between two adjacent cooling fans 8 out of the plurality of cooling fans 8, if any one of the plurality of cooling fans 8 is stopped, it is possible to suppress outside air from flowing into the cooling fans 8 being operated from the stopped cooling fan 8, thereby suppressing reduction of the cooling capacity.

Further, according to the present embodiment, the portion downstream of the portion 322ap provided with the cover-side heat dissipation fins 322a is gradually narrowed from the flow path width W7 of the portion 322ap provided with the cover-side heat dissipation fins 322a to the flow path width W6 of the communication flow path portion 323.

Consequently, cooling air CA having passed through the portion 322ap provided with the cover-side heat dissipation fins 322a in the cooling air flow path AD flows into the portion 321ap provided with the base-side heat dissipation fins 321a, without colliding with the side walls of the cooling air flow path AD. This can suppress the increase in flow resistance.

### Fourth Embodiment

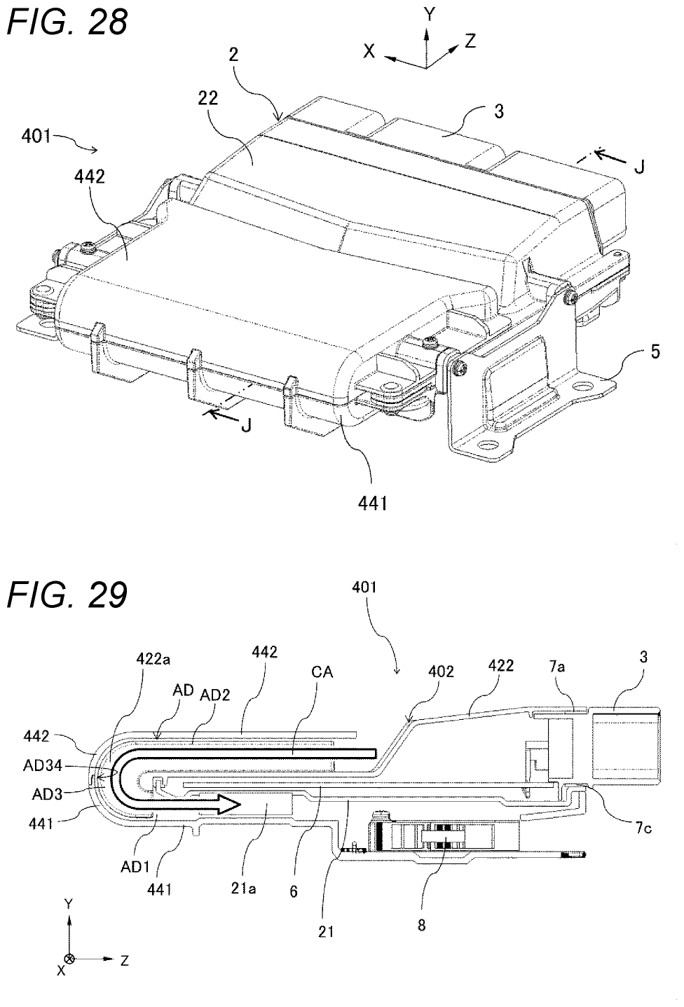

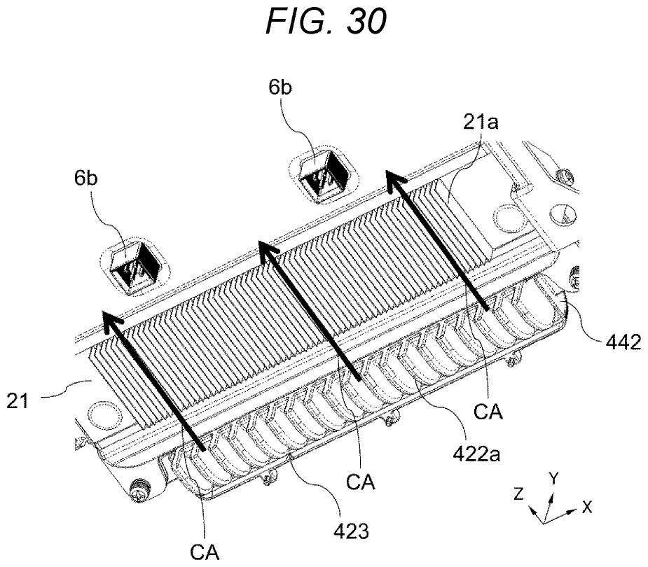

FIG. 28 is a perspective view of an electronic control device 401 according to a fourth embodiment of the present invention as viewed from the left thereof, thereabove and therebehind (from above the rear side of an external connection connector rear side). FIG. 29 is a cross-sectional view taken along a line J-J in FIG. 28. FIG. 30 is a perspective view of the rear side of the back surface of a housing 402 according to the fourth embodiment of the present invention.

As illustrated in FIGS. 8 and 29, both the cooling air flow paths AD in the electronic control device 1 according to the first embodiment and in the electronic control device 401 according to the present embodiment include a first flow path portion AD1 positioned near the lower surface of the housing, a second flow path portion AD2 positioned near the upper surface of the housing, and a communication flow path portion AD3 connecting the first flow path portion AD1 and the second flow path portion AD2 to each other.

On the other hand, as illustrated in FIG. 8, in the electronic control device 1 according to the first embodiment, there is no heat dissipation fin in the communication flow path portion AD3. On the other hand, in the electronic control device 401 according to the present embodiment, first heat dissipation fins or second heat dissipation fins extend from one of the first flow path portion AD1 and the second flow path portion AD2 up to the communication flow path portion AD3. For example, as illustrated in FIGS. 29 and 30, the cover-side heat dissipation fins 422a may extend up to the communication flow path portion AD3.

As illustrated in FIG. 8, in the electronic control device 1 according to the first embodiment, the communication flow path portion AD3 has an inner wall AD31 with a flat surface. On the other hand, in the electronic control device 401 according to the present embodiment, the communication flow path portion AD3 has an inner wall AD34 with a curved surface, as illustrated in FIG. 29.

### Effects

In the electronic control device 401 according to the present embodiment, at least the first heat dissipation fins or the second heat dissipation fins (in the present embodiment, the cover-side heat dissipation fins 422a as the second heat dissipation fins) extend up to the communication flow path portion AD3. Therefore, cooling air CA flowing through the communication flow path portion AD3 is rectified by the heat dissipation fins. This can suppress cooling air CA from flowing unevenly in the leftward and rightward direction of the communication flow path portion AD3, thereby suppressing variations in cooling performance in the leftward and rightward direction.

On the other hand, in the electronic control device 401 according to the present embodiment, the inner wall AD34 of the communication flow path portion AD3 has a curved surface, as illustrated in FIG. 29. Therefore, cooling air CA flowing from the second flow path portion AD2 into the communication flow path portion AD3 flows along the curved surface of the inner wall AD34 and flows out to the first flow path portion AD1. This can change the direction of flow of cooling air CA, while suppressing the increase of the flow resistance.

Incidentally, the present invention is not limited to the aforementioned embodiments, and includes various modifications. For example, the aforementioned embodiments have been described in detail for facilitating understanding of the present invention, and the present invention is not necessarily limited to the structure including all the described structures. Further, the structure according to one embodiment can be partially replaced with the structure according to another embodiment, and, also, the structure according to one embodiment can be additionally provided with the structure according to another embodiment. Further, the structure according to each embodiment can be partially provided with other additional structures, eliminated or replaced with other structures.

For example, although there has been described the electronic control device 1 according to the embodiment, where the partition 41cb is provided between two adjacent cooling fans 8 out of the plurality of cooling fans 8, the partition 41cb may be eliminated.

### REFERENCE SIGNS LIST

1 electronic control device
2 housing
3 external connection connector
4 air duct
5 device-side bracket
6 circuit board
6a electronic component
6b power supply connector
6f through hole
6g Thermal via
6h heat dissipation grease
7 sealing material
8 cooling fan
8a fan connector
8aa latch locking portion
8c cable
21 base
21a base-side heat dissipation fin
22 cover
22a cover-side heat dissipation fin
22c positioning male portion
22d positioning female portion
41ca attachment-surface limiting configuration
41cb partition
41d connector fixing portion
41db latch engagement portion
41e cable storage portion
41f positioning male portion
41i fin facing portion
41j level difference
42 cover-side air duct
42g positioning female portion
48 subassembly
201 electronic control device
204 air duct
205 device-side bracket
208 axial fan
241 base-side air duct
241c cooling fan fixing portion
241ca boss
241cc air exhaust port
248 subassembly
301 electronic control device
321a base-side heat dissipation fin
322a cover-side heat dissipation fin
323 communication flow path portion
341 base-side air duct
342 cover-side air duct
401 electronic control device
402 housing
422a cover-side heat dissipation fin

1. An electronic control device comprising:
a circuit board having a plurality of electronic components mounted thereon;
a housing adapted to seal and house the circuit board;
a first heat dissipation fin comprising a plurality of protrusions provided on a lower surface of the housing;
a second heat dissipation fin comprising a plurality of protrusions provided on an upper surface of the housing;
an air duct attached to an outer side of the housing so as to cover the first heat dissipation fin and the second heat dissipation fin and adapted to form a cooling air flow path for flowing cooling air therethrough near the upper surface and the lower surface of the housing; and
a cooling fan installed downstream of the heat dissipation fin positioned in a downstream side of the cooling air flow path, out of the first heat dissipation fin and the second heat dissipation fin, and adapted to exhaust cooling air toward the downstream side of the cooling air flow path;
wherein the cooling air flow path is formed to be a single flow path without branching, through a portion from the first heat dissipation fin up to the second heat dissipation fin.

2. The electronic control device according to claim 1, wherein, in the cooling air flow path, out of two portions provided with the first heat dissipation fin and the second heat dissipation fin, at least one portion has a flow path cross-sectional area smaller than a flow path cross-sectional area of a portion upstream of the at least one portion.

3. The electronic control device according to claim 2, wherein the heat dissipation fin provided in the at least one portion, out of the first heat dissipation fin and the second heat dissipation fin, is formed through skiving.

4. The electronic control device according to claim 1, wherein the cooling fan comprises a plurality of cooling fans fixed to the air duct and arranged in parallel with respect to a flow of cooling air.

5. The electronic control device according to claim 4, further comprising a partition provided between two adjacent cooling fans, out of the plurality of cooling fans.

6. The electronic control device according to claim 4, wherein in the cooling air flow path, a portion provided with the plurality of cooling fans has a larger flow path width than a flow path width of a portion provided with the heat dissipation fin positioned upstream of the plurality of cooling fans, out of the first heat dissipation fin and the second heat dissipation fin.

7. The electronic control device according to claim 1, further comprising a temperature sensor,
wherein a rotational speed of the cooling fan is controlled based on a value detected by the temperature sensor.

8. The electronic control device according to claim 1, further comprising
a fan connector connected electrically to the cooling fan through a cable, and
a power supply connector connected electrically to the circuit board and fixed to the housing,
wherein the fan connector is detachably connected to the power supply connector, and
the cooling fan and the fan connector are secured to the air duct.

9. The electronic control device 1 according to claim 1, wherein the cooling fan is secured to the vehicle so as to be positioned closer to the vehicle than to the housing.

10. The electronic control device according to claim 1, wherein
the cooling air flow path includes a first flow path portion positioned near the lower surface of the housing, a second flow path portion positioned near the upper surface of the housing, and a communication flow path portion connecting the first flow path portion and the second flow path portion to each other, and
one of the first heat dissipation fin and the second heat dissipation fin extends from one of the first flow path portion and the second flow path portion up to the communication flow path portion.

11. The electronic control device according to claim 1, wherein the plurality of electronic components are arranged in parallel with respect to a direction of flow of the cooling air.

12. The electronic control device according to claim 1, wherein a dimension of a gap formed between the air duct and a tip end of the first heat dissipation fin or the second heat dissipation fin is set such that a flow rate of cooling air passing between the air duct and the tip end of the first heat dissipation fin or the second heat dissipation fin is smaller than a flow rate of cooling air passing between two adjacent protrusions out of the plurality of protrusions included in the first heat dissipation fin or the second heat dissipation fin.

13. The electronic control device according to claim 1, wherein
the cooling fan comprises an axial fan, and
a bracket for attaching the electronic control device to an object to which the electronic control device is to be attached is adapted to maintain an interval between an air exhaust port in the air duct and the object to which the electronic control device is to be attached, at a predetermined value.

14. The electronic control device according to claim 1, wherein the plurality of electronic components are in contact with the housing with a heat dissipation grease interposed between the electronic components and the housing.

15. The electronic control device according to claim 1, wherein the housing and the air duct are provided with an attachment-position limiting configuration for limiting the position at which the housing and the air duct are attached to each other.

16. The electronic control device according to claim 1, wherein the air duct is provided with an attachment-surface limiting configuration for limiting an attachment surface of the cooling fan.

17. The electronic control device according to claim 8, wherein the air duct is provided with a cable storage portion for storing an extra length of the cable.

18. The electronic control device according to claim 8, wherein
the power supply connector is attached to the circuit board and inserted in a through hole provided in the housing, and
a sealing material is provided in a gap formed between the through hole and the power supply connector.

19. The electronic control device according to claim 8, wherein the fan connector and the air duct are provided with a latch mechanism for coupling the fan connector and the air duct to each other.

20. The electronic control device according to claim 10, wherein the communication flow path portion has an inner wall with a curved surface.
